(19) United States
(12) Patent Application Publication
(10) Pub. No.: US 2024/0413045 A1
(43) Pub. Date: Dec. 12, 2024

(54) SEMICONDUCTOR MODULE AND HEAT DISSIPATION PLATE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Masayuki KAMIYA, Nisshin-shi (JP)

(21) Appl. No.: 18/661,813

(22) Filed: May 13, 2024

(30) Foreign Application Priority Data
Jun. 12, 2023 (JP) 2023-096298

(51) Int. Cl. H01L 23/373

(52) U.S. Cl. CPC H01L 23/3735

(57) ABSTRACT

A heat dissipation plate of a semiconductor module includes a first heat dissipation portion and a second heat dissipation portion formed of a material having anisotropic thermal conductivity. The first heat dissipation portion includes a position facing a semiconductor element in a thickness direction of the heat dissipation plate, and has higher thermal conductivity in a planar direction of a first virtual plane parallel to the thickness direction than in a direction perpendicular to the planar direction of the first virtual plane. The second heat dissipation portion is connected to the first heat dissipation portion in a direction parallel to the planar direction of the first virtual plane and perpendicular to the thickness direction, and has higher thermal conductivity in a planar direction of a second virtual plane perpendicular to the thickness direction than in a direction perpendicular to the planar direction of the second virtual plane.

### CROSS REFERENCE TO RELATED APPLICATION

The present application claims the benefit of priority from Japanese Patent Application No. 2023-096298 filed on Jun. 12, 2023. The entire disclosure of the above application is incorporated herein by reference.

### TECHNICAL FIELD

The present disclosure relates to a semiconductor module and a heat dissipation plate.

### BACKGROUND

There has been known a semiconductor module including a semiconductor element and a heat dissipation plate that dissipates heat generated by the semiconductor element.

### SUMMARY

A semiconductor module according to a first aspect of the present disclosure includes a heat dissipation plate having a plate shape, and a semiconductor element mounted to the heat dissipation plate in a thickness direction of the heat dissipation plate and generating heat when supplied with electricity. The heat dissipation plate includes a first heat dissipation portion and a second heat dissipation portion formed of a material having anisotropic thermal conductivity. The first heat dissipation portion includes a position facing the semiconductor element in the thickness direction, and has higher thermal conductivity in a planar direction of a first virtual plane parallel to the thickness direction than in a direction perpendicular to the planar direction of the first virtual plane. The second heat dissipation portion is connected to the first heat dissipation portion in a direction parallel to the planar direction of the first virtual plane and perpendicular to the thickness direction, and has higher thermal conductivity in a planar direction of a second virtual plane perpendicular to the thickness direction than in a direction perpendicular to the planar direction of the second virtual plane.

A heat dissipation plate according to a second aspect of the present disclosure includes a first heat dissipation portion and a second heat dissipation portion formed of a material having anisotropic thermal conductivity. The first heat dissipation portion includes a position to face a semiconductor element that is to be mounted to the heat dissipation plate in a thickness direction of the heat dissipation plate, and has higher thermal conductivity in a planar direction of a first virtual plane parallel to the thickness direction than in a direction perpendicular to the planar direction of the first virtual plane. The second heat dissipation portion is connected to the first heat dissipation portion in a direction parallel to the planar direction of the first virtual plane and perpendicular to the thickness direction, and has higher thermal conductivity in a planar direction of a second virtual plane perpendicular to the thickness direction than in a direction perpendicular to the planar direction of the second virtual plane.

### BRIEF DESCRIPTION OF DRAWINGS

Objects, features and advantages of the present disclosure will become apparent from the following detailed description made with reference to the accompanying drawings. In the drawings:

FIG. 1 is a perspective view of a semiconductor module and a cooler according to a first embodiment;

FIG. 2 is a plan view of the semiconductor module as viewed in the direction of arrow Il in FIG. 1;

FIG. 3 is a schematic diagram showing a molecular structure of graphite;

FIG. 4 is a plan view of a semiconductor module according to a first comparative example;

FIG. 5 is an explanatory view for explaining how heat is transferred when a semiconductor element generates heat in the semiconductor module according to the first comparative example;

FIG. 6 is an explanatory view for explaining how heat is transferred when a semiconductor element generates heat in a semiconductor module according to a second comparative example;

FIG. 7 is a perspective view of a semiconductor module according to a second embodiment;

FIG. 8 is a plan view of the semiconductor module as viewed in the direction of arrow VIII in FIG. 7;

FIG. 9 is a perspective view of a semiconductor module according to a third embodiment;

FIG. 10 is a plan view of the semiconductor module as viewed in the direction of the arrow X in FIG. 9;

FIG. 11 is a plan view of a semiconductor module according to a fourth embodiment;

FIG. 12 is a plan view of a semiconductor module according to a fifth embodiment;

FIG. 13 is a plan view of a semiconductor module according to a sixth embodiment;

FIG. 14 is a plan view of a semiconductor module according to a seventh embodiment;

FIG. 15 is a plan view of a semiconductor module according to an eighth embodiment;

FIG. 16 is a perspective view of a semiconductor module according to a ninth embodiment;

FIG. 17 is a perspective view of a semiconductor module according to a tenth embodiment;

FIG. 18 is a perspective view of a semiconductor module according to an eleventh embodiment;

FIG. 19 is a perspective view of a semiconductor module according to a twelfth embodiment;

FIG. 20 is a plan view of a semiconductor module according to a thirteenth embodiment;

FIG. 21 is a plan view of a semiconductor module according to a fourteenth embodiment;

FIG. 22 is a perspective view of a semiconductor module according to a fifteenth embodiment;

FIG. 23 is a diagram showing an analysis of a temperature distribution during heat generation of a semiconductor element in a plan view of the semiconductor module according to the fifteenth embodiment;

FIG. 24 is a diagram showing an analysis of a temperature distribution during heat generation of the semiconductor element in a cross-sectional view taken along line XXIV-XXIV in FIG. 23;

FIG. 25 is a perspective view of a semiconductor module according to a third comparative example;

FIG. 26 is a diagram showing an analysis of a temperature distribution during heat generation of a semiconductor element in a plan view of the semiconductor module according to the third comparative example;

FIG. 27 is a diagram showing an analysis of a temperature distribution during heat generation of the semiconductor element in a cross-sectional view taken along line XXVII-XXVII in FIG. 26;

FIG. 28 is a perspective view of a semiconductor module according to a sixteenth embodiment;

FIG. 29 is a cross-sectional view of a semiconductor module according to a seventeenth embodiment, taken along a plane parallel to a thickness direction of a heat dissipation plate;

FIG. 30 is a perspective view of a semiconductor module according to an eighteenth embodiment;

FIG. 31 is a cross-sectional view of the semiconductor module according to the eighteenth embodiment, taken along a plane parallel to a thickness direction of a heat dissipation plate;

FIG. 32 is a cross-sectional view of a semiconductor module according to a nineteenth embodiment, taken along a plane parallel to a thickness direction of a heat dissipation plate;

FIG. 33 is a perspective view of a semiconductor module and a cooler according to a twentieth embodiment; and

FIG. 34 is a plan view of the semiconductor module as viewed in the direction of arrow XXXIV in FIG. 33.

### DETAILED DESCRIPTION

Next, a relevant technology is described only for understanding the following embodiments. A semiconductor module according to the relevant technology includes a semiconductor element and a heat dissipation plate that dissipates heat generated by the semiconductor element. The heat dissipation plate is also called a heat spreader. The heat dissipation plate includes a first heat spreader and a second heat spreader and has a rectangular shape as viewed from a thickness direction of the heat dissipation plate. Each of the first heat spreader and the second heat spreader is formed of graphite which is a material having anisotropy in thermal conductivity. The first heat spreader has high thermal conductivity in a planar direction of a first virtual plane parallel to the thickness direction of the heat dissipation plate. The second heat spreader is connected to the first heat spreader in a direction perpendicular to the first virtual plane. The second heat spreader has high thermal conductivity in a planar direction of a second virtual plane perpendicular to the first virtual plane. The semiconductor element is disposed to overlap both the first heat spreader and the second heat spreader. According to the above configuration, heat generated from the semiconductor element spreads into the heat dissipation plate via the first heat spreader and the second heat spreader, and is dissipated from a surface of the heat dissipation plate opposite to the semiconductor element.

However, the semiconductor module described above has a configuration in which the heat generated from the semiconductor element is less likely to be transferred to four corner portions of the heat dissipation plate having the rectangular shape due to the anisotropy of the thermal conductivity of the first heat spreader and the second heat spreader and the arrangement of the first heat spreader and the second heat spreader. Therefore, in the semiconductor module, the entire region of the heat dissipation plate cannot be effectively utilized, and thus there is room for improvement.

A semiconductor module according to a first aspect of the present disclosure includes a heat dissipation plate having a plate shape, and a semiconductor element mounted to the heat dissipation plate in a thickness direction of the heat dissipation plate and generating heat when supplied with electricity. The heat dissipation plate includes a first heat dissipation portion and a second heat dissipation portion formed of a material having anisotropic thermal conductivity. The first heat dissipation portion includes a position facing the semiconductor element in the thickness direction, and has higher thermal conductivity in a planar direction of a first virtual plane parallel to the thickness direction than in a direction perpendicular to the planar direction of the first virtual plane. The second heat dissipation portion is connected to the first heat dissipation portion in a direction parallel to the planar direction of the first virtual plane and perpendicular to the thickness direction, and has higher thermal conductivity in a planar direction of a second virtual plane perpendicular to the thickness direction than in a direction perpendicular to the planar direction of the second virtual plane.

According to this configuration, the heat transferred from the semiconductor element to the first heat dissipation portion spreads in the planar direction of the first virtual plane at the position of the first heat dissipation portion facing the semiconductor element. Therefore, a part of the heat transferred from the semiconductor element to the first heat dissipation portion is dissipated from a surface of the first heat dissipation portion opposite to the semiconductor element, and the remaining part is transferred to the second heat dissipation portion. The heat transferred to the second heat dissipation portion spreads in the second heat dissipation portion in the planar direction of the second virtual plane that is perpendicular to the thickness direction of the heat dissipation plate. Therefore, the heat is transferred from the second heat dissipation portion to a position different from the position facing the semiconductor element in the first heat dissipation portion while spreading in the second heat dissipation portion.

The heat transferred from the second heat dissipation portion to the first heat dissipation portion is dissipated from the surface of the first heat dissipation portion opposite to the semiconductor element while spreading in the planar direction of the first virtual surface in the first heat dissipation portion. Since the second heat dissipation portion functioning as a heat direction changing portion is disposed outside the first heat dissipation portion, it is possible to spread the heat generated by the semiconductor element to substantially the entire region of the heat dissipation plate and dissipate the heat in the thickness direction of the heat dissipation plate. Therefore, in the semiconductor module according to the first aspect, an area where the heat dissipation plate functions as a heat dissipation surface can be increased, and a heat dissipation performance of the heat dissipation plate can be improved.

In the present disclosure, “perpendicular” includes a substantially perpendicular state due to, for example, manufacturing tolerance, and “parallel” includes a substantially parallel state due to, for example, manufacturing tolerance. In addition, in the present disclosure, “the heat dissipation portion has high thermal conductivity in a planar direction of a predetermined virtual plane” means that, in the heat dissipation portion, the thermal conductivity in the planar direction of the predetermined virtual plane is larger than the thermal conductivity in a direction perpendicular to the predetermined virtual plane. The heat dissipation plate only needs to include at least the first heat dissipation portion and the second heat dissipation portion, and may include other heat dissipation portions.

A heat dissipation plate according to a second aspect of the present disclosure includes a first heat dissipation portion and a second heat dissipation portion formed of a material having anisotropic thermal conductivity. The first heat dissipation portion includes a position to face a semiconductor element that is to be mounted to the heat dissipation plate in a thickness direction of the heat dissipation plate, and has higher thermal conductivity in a planar direction of a first virtual plane parallel to the thickness direction than in a direction perpendicular to the planar direction of the first virtual plane. The second heat dissipation portion is connected to the first heat dissipation portion in a direction parallel to the planar direction of the first virtual plane and perpendicular to the thickness direction, and has higher thermal conductivity in a planar direction of a second virtual plane perpendicular to the thickness direction than in a direction perpendicular to the planar direction of the second virtual plane.

According to this configuration, the heat dissipation plate according to the second aspect can also spread the heat generated by the semiconductor element to substantially the entire region of the heat dissipation plate and dissipate the heat in the thickness direction of the heat dissipation plate as described in the first aspect. Therefore, the semiconductor module using this heat dissipation plate can improve heat dissipation.

Embodiments of the present disclosure will now be described with reference to the drawings. In the following embodiments, the same or equivalent portions are denoted by the same reference numerals, and the description thereof will be omitted.

### First Embodiment

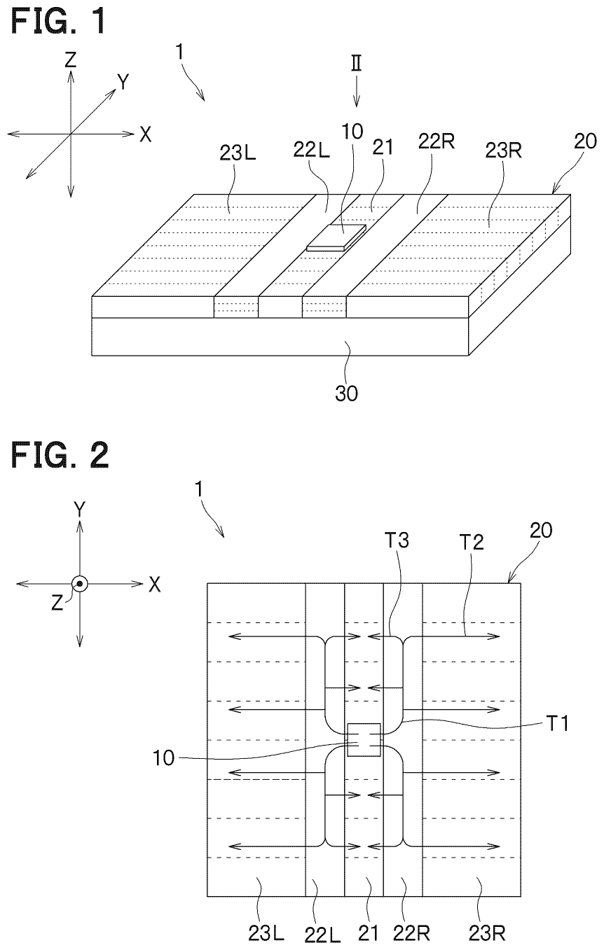

A first embodiment will be described with reference to the drawings. As shown in FIG. 1 and FIG. 2, a semiconductor module 1 according to the first embodiment includes a semiconductor element 10, a heat dissipation plate 20, and the like.

The semiconductor element 10 is a heat generating element that generates heat when supplied with electricity, and is, for example, a power semiconductor element such as a diode, a metal oxide semiconductor field effect transistor (MOSFET), and an insulated gate bipolar transistor (IGBT). The power semiconductor element is formed of, for example, silicon (Si), silicon carbide (SiC), gallium nitride (GaN), gallium oxide (Ga₂O₃), or the like. The semiconductor element 10 is mounted to one surface of the heat dissipation plate 20 facing in a thickness direction of the heat dissipation plate 20. Hereinafter, the one surface to which the semiconductor element is mounted is referred to as an “element mounting surface”.

The heat dissipation plate 20 has a plate shape. For example, a cooler 30 is disposed on a surface of the heat dissipation plate 20 opposite to the element mounting surface. Hereinafter the surface of the heat dissipation plate 20 on which the cooler 30 is disposed is referred to as a “cooling surface”. Instead of or in addition to the cooler 30, a heat radiator, a heat exchanger, or the like may be disposed. Heat generated by the semiconductor element 10 spreads to the heat dissipation plate 20 and is dissipated from the cooling surface.

The heat dissipation plate 20 includes a first heat dissipation portion 21, second heat dissipation portions 22, and third heat dissipation portions 23. In the description of the first embodiment and the drawings referred to in the description, alphabetic symbols R and L indicating the positions of the respective heat dissipation portions are added to ends of the numerical symbols 22 and 23 that indicate the second heat dissipation portions 22 and the third heat dissipation portions 23, respectively. This also applies to the description of the fourth to twelfth and fifteenth to twentieth embodiments described later and the drawings referred to in the description.

In the first embodiment, as shown in FIG. 2, the two second heat dissipation portions 22R and 22L and the two third heat dissipation portions 23R and 23L are disposed to the right and the left of the first heat dissipation portion 21. Each of the first heat dissipation portion 21, the second heat dissipation portions 22, and the third heat dissipation portions 23 is formed of a material having anisotropic thermal conductivity. The material having anisotropic thermal conductivity is, for example, graphite.

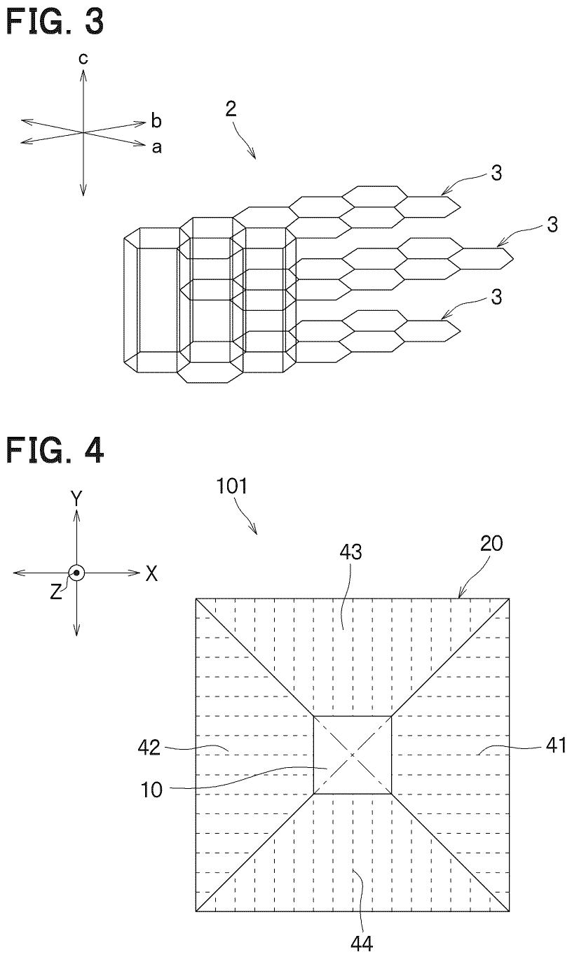

As shown in FIG. 3, a graphite 2 has a molecular structure in which multiple layers of graphene 3 are stacked in a layered manner. In the graphene 3, hexagonal lattice structures in which carbon atoms are bonded are two-dimensionally spread. In the graphite 2, a thermal conductivity in a planar direction of the graphene 3 is higher than a thermal conductivity in the stacking direction of the multiple layers of the graphene 3. Specifically, in three-dimensional coordinates of an a-axis, a b-axis, and a c-axis shown in FIG. 3, the graphite 2 has a high thermal conductivity in the planar direction of the ab plane and a low thermal conductivity in the direction in which the c-axis extends (hereinafter, referred to as a “c-axis direction”). In general, the graphite 2 has a thermal conductivity of about 1700 W/m·K in the planar direction of the ab plane and a thermal conductivity of about 7 W/m·K in the c-axis direction. The thermal conductivity of copper generally used as a heat dissipation material is about 400 W/m·K. Therefore, by utilizing the anisotropy of the thermal conductivity of the graphite 2, it is possible to configure the heat dissipation plate 20 having higher heat dissipation performance than a copper plate.

In FIG. 1 and FIG. 2, the layers of the graphene 3 constituting the graphite 2 in the first heat dissipation portion 21, the second heat dissipation portions 22, and the third heat dissipation portions 23 are schematically shown by broken lines. In FIG. 1 and FIG. 2, boundary lines between the first heat dissipation portion 21, the second heat dissipation portions 22, and the third heat dissipation portions 23 are indicated by solid lines. However, in practice, the first heat dissipation portion 21, the second heat dissipation portions 22, and the third heat dissipation portions 23 are integrally formed. In three-dimensional coordinates of an X-axis, a Y-axis, and a Z-axis shown in FIG. 1 and FIG. 2, a direction in which the Z-axis extends coincides with the thickness direction of the heat dissipation plate 20. In addition, the direction in which the first heat dissipation portion 21, the second heat dissipation portions 22, and the third heat dissipation portions 23 are arranged coincides with a direction in which the X-axis extends. In the following description, the direction in which the X axis extends is referred to as an “X-axis direction”, a direction in which the Y-axis extends is referred to as a “Y-axis direction”, and a direction in which the Z-axis extends is referred to as a “Z-axis direction”. The same applies to the description of the second to twentieth embodiments and the first to third comparative examples to be described later and the drawings referred to in the description.

As shown in FIG. 1 and FIG. 2, the first heat dissipation portion 21 is a portion including a position facing the semiconductor element 10 in the thickness direction of the heat dissipation plate 20. In the following description, the position of the first heat dissipation portion 21 facing the semiconductor element 10 in the thickness direction of the heat dissipation plate 20 is referred to as a “position of the first heat dissipation portion 21 directly below the semiconductor element 10”.

The first heat dissipation portion 21 has high thermal conductivity in a planar direction of a first virtual plane that is a plane parallel to the thickness direction of the heat dissipation plate 20. In other words, the first heat dissipation portion 21 has higher thermal conductivity in the planar direction of the first virtual plane than a direction perpendicular to the planar direction of the first virtual plane. In the first embodiment, the first virtual plane is an XZ plane. Therefore, the first heat dissipation portion 21 has high thermal conductivity in the planar direction of the XZ plane. The first heat dissipation portion 21 has a portion extending in a direction perpendicular to the planar direction of the first virtual plane from the position directly below the semiconductor element 10 in addition to the position directly below the semiconductor element 10.

The second heat dissipation portions 22 are portions connected to the first heat dissipation portion 21 in a direction parallel to the planar direction of the first virtual plane and perpendicular to the thickness direction. Specifically, the second heat dissipation portions 22 are portions connected to the first heat dissipation portion 21 in the X-axis direction. More specifically, the second heat dissipation portions 22 are connected to portions of the first heat dissipation portion 21 extending in a direction parallel to the planar direction of the first virtual plane and perpendicular to the thickness direction of the heat dissipation plate 20 from the position directly below the semiconductor element 10. At the same time, the second heat dissipation portions 22 are also connected to portions of the first heat dissipation portion 21 extending in a direction perpendicular to the planar direction of the first virtual plane from the position directly below the semiconductor element 10. In other words, the second heat dissipation portions 22 are connected to the portions of the first heat dissipation portion 21 extending in the X-axis direction from the position directly below the semiconductor element 10, and are also connected in the X-axis direction to the portions of the first heat dissipation portion 21 extending in the Y-axis direction from the position directly below the semiconductor element 10.

In the first embodiment, the heat dissipation plate 20 has two second heat dissipation portions 22. Of the two second heat dissipation portions 22, one disposed to one side in the X-axis direction, that is, the right of the first heat dissipation portion 21 is referred to as a right second heat dissipation portion 22R, and one disposed to the other side in the X-axis direction, that is, the left of the first heat dissipation portion 21 is referred to as a left second heat dissipation portion 22L.

The second heat dissipation portions 22 have high thermal conductivity in a planar direction of a second virtual plane that is perpendicular to the thickness direction of the heat dissipation plate 20. In other words, the second heat dissipation portions 22 have higher thermal conductivity in a planar direction of the second virtual plane than in a direction perpendicular to the planar direction of the second virtual plane. In the first embodiment, the second virtual plane is an XY plane. Therefore, the second heat dissipation portions 22 have high thermal conductivity in the planar direction of the XY plane.

The third heat dissipation portions 23 are portions connected to the second heat dissipation portions 22 in a direction parallel to the planar direction of the second virtual plane. In the first embodiment, the first heat dissipation portion 21, the second heat dissipation portions 22, and the third heat dissipation portions 23 are arranged in the X-axis direction. Therefore, the third heat dissipation portions 23 are portions connected to the second heat dissipation portions 22 in the X-axis direction. In the first embodiment, the heat dissipation plate 20 has two third heat dissipation portions 23. Of the two third heat dissipation portions 23, one disposed to the one side in the X-axis direction, that is, the right of the right second heat dissipation portion 22R is referred to as a right third heat dissipation portion 23R, and one disposed to the other side in the X-axis direction, that is, the left of the left second heat dissipation portion 22L is referred to as a left third heat dissipation portion 23L.

A plane that is not perpendicular to the direction in which the third heat dissipation portions 23 are connected to the second heat dissipation portion 22 and is parallel to the thickness direction of the heat dissipation plate 20 is referred to as a third virtual plane. The third heat dissipation portions 23 have high thermal conductivity in a planar direction of the third virtual plane. In other words, the third heat dissipation portions 23 have higher thermal conductivity in the planar direction of the third virtual plane than in a direction perpendicular to the planar direction of the third virtual plane. In the first embodiment, the third virtual plane is a plane parallel to the direction in which the third heat dissipation portions 23 are connected to the second heat dissipation portions 22 and parallel to the thickness direction of the heat dissipation plate 20. Therefore, the third virtual plane is the XZ plane similarly to the first virtual plane. Therefore, the third heat dissipation portion 23 has high thermal conductivity in the planar direction of the XZ plane.

In FIG. 2, a part of paths through which heat generated from the semiconductor element 10 is transferred to the heat dissipation plate 20 is schematically indicated by arrows.

The heat generated from the semiconductor element 10 is transferred to the position of the first heat dissipation portion 21 directly below the semiconductor element 10, and then transferred to the second heat dissipation portions 22 in the X-axis direction from the position as indicated by arrows T1 in FIG. 2. Then, the heat spreads along the XY plane in the second heat dissipation portions 22. Although the arrows are omitted, a part of the heat transferred from the semiconductor element 10 to the position directly below the semiconductor element 10 in the first heat dissipation portion 21 spreads along the XZ plane at the position directly below the semiconductor element 10 in the first heat dissipation portion 21, and is dissipated from the cooling surface of the first heat dissipation portion 21.

As indicated by arrows T2, a part of the heat spreading along the XY plane in the second heat dissipation portions 22 is transferred to the third heat dissipation portions 23. Then, the heat spreads in the third heat dissipation portions 23 along the XZ plane and is dissipated from the cooling surfaces of the third heat dissipation portions 23.

As indicated by arrows T3, another part of the heat spreading along the XY plane in the second heat dissipation portions 22 is transferred to the portions of the first heat dissipation portion 21 extending in the Y-axis direction from the position directly below the semiconductor element 10. Then, the heat spreads along the XZ plane at the portions of the first heat dissipation portion 21 extending in the Y-axis direction from the position directly below the semiconductor element 10, and is dissipated from the cooling surface of the first heat dissipation portion 21.

As described above, in the first embodiment, the second heat dissipation portions 22 are used as heat direction changing portions. Thus, it is possible to spread the heat generated by the semiconductor element 10 to substantially the entire region of the heat dissipation plate 20 and dissipate the heat from the cooling surface of the heat dissipation plate 20. Therefore, in the semiconductor module 1, an area where the heat dissipation plate 20 functions as a heat dissipation surface can be increased, and the heat dissipation performance of the heat dissipation plate 20 can be improved.

Next, semiconductor modules of a first comparative example and a second comparative example will be described for comparison with the semiconductor module 1 described in the first embodiment.

### First Comparative Example

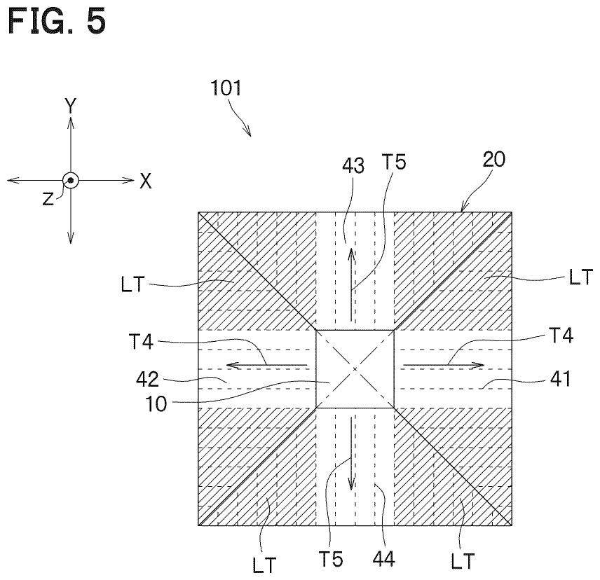

As shown in FIG. 4, a heat dissipation plate 20 included in a semiconductor module 101 of the first comparative example has four heat dissipation portions radially arranged around the semiconductor element 10. For convenience of description, among the four heat dissipation portions, the heat dissipation portion disposed to the right of the semiconductor element 10 in FIG. 4 is referred to as a right heat dissipation portion 41, and the heat dissipation portion disposed to the left of the semiconductor element 10 in FIG. 4 is referred to as a left heat dissipation portion 42. In addition, the heat dissipation portion disposed to an upper side of the semiconductor element 10 in FIG. 4 is referred to as an upper heat dissipation portion 43, and the heat dissipation portion disposed to a lower side of the semiconductor element 10 in FIG. 4 is referred to as a lower heat dissipation portion 44. In FIG. 4 and FIG. 5, portions of boundary lines of the four heat dissipation portions 41 to 44 below the semiconductor element 10 are indicated by alternate long and short dash lines.

The right heat dissipation portion 41 and the left heat dissipation portion 42 have high thermal conductivity in the planar direction of the XZ plane. The upper heat dissipation portion 43 and the lower heat dissipation portion 44 have high thermal conductivity in the planar direction of the YZ plane.

In FIG. 5, a part of heat paths through which heat generated from the semiconductor element 10 is transferred to the heat dissipation plate 20 is schematically indicated by arrows.

As indicated by arrows T4 in FIG. 5, the heat generated from the semiconductor element 10 is transferred in the X-axis direction in a range of the width of the semiconductor element 10 in the right heat dissipation portion 41 and the left heat dissipation portion 42. In addition, as indicated by arrows T5 in FIG. 5, the heat generated from the semiconductor element 10 is transferred in the Y-axis direction in a range of the width of the semiconductor element 10 in the upper heat dissipation portion 43 and the left heat dissipation portion 42. Therefore, as indicated by hatching LT in FIG. 5, a region to which heat is hardly transferred is formed outside the region to which heat is transferred in the X-axis direction and the Y-axis direction in the range of the width of the semiconductor element 10. Therefore, the semiconductor module 101 of the first comparative example cannot effectively utilize the entire region of the heat dissipation plate 20.

### Second Comparative Example

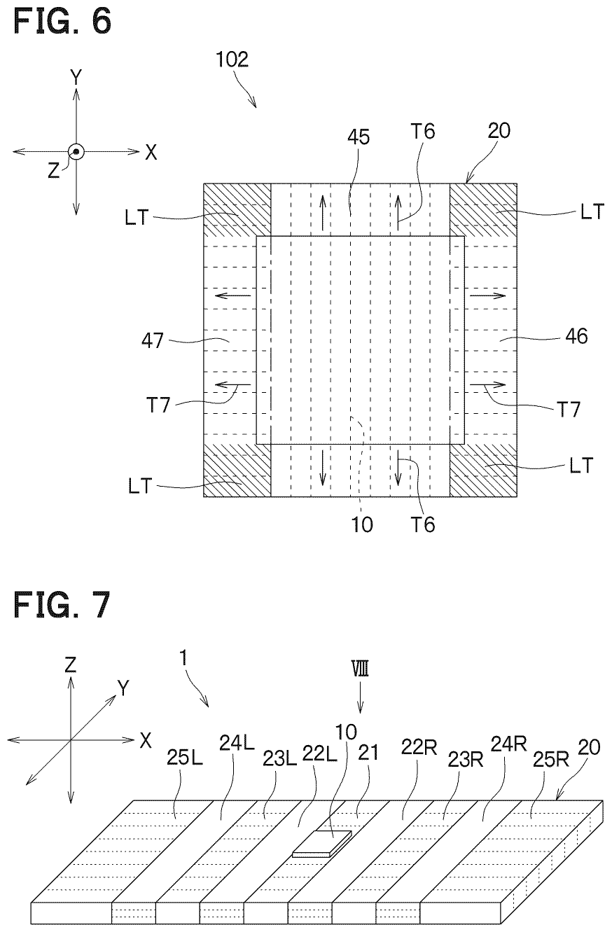

As shown in FIG. 6, a heat dissipation plate 20 included in a semiconductor module 102 of the second comparative example has three heat dissipation portions. For convenience of description, among the three heat dissipation portions, a heat dissipation portion extending in the Y-axis direction and including a position directly below the semiconductor element 10 is referred to as a vertical heat dissipation portion 45. In addition, a heat dissipation portion disposed to the right of the vertical heat dissipation portion 45 in FIG. 6 is referred to as a right lateral heat dissipation portion 46, and a heat dissipation portion disposed to the left of the vertical heat dissipation portion 45 in FIG. 6 is referred to as a left lateral heat dissipation portion 47. In FIG. 6, portions of boundary lines of the three heat dissipation portions 45 to 47 below the semiconductor element 10 are indicated by alternate long and short dash lines.

The vertical heat dissipation portion 45 has high thermal conductivity in the planar direction of the YZ plane. The right lateral heat dissipation portion 46 and the left lateral heat dissipation portion 47 have high thermal conductivity in the planar direction of the XZ plane. The semiconductor element 10 is disposed such that at least a part of the semiconductor element 10 overlaps the vertical heat dissipation portion 45, the right lateral heat dissipation portion 46, and the left lateral heat dissipation portion 47 in the thickness direction of the heat dissipation plate 20.

In FIG. 6, a part of heat paths through which heat generated from the semiconductor element 10 is transferred to the heat dissipation plate 20 is schematically indicated by arrows.

As indicated by arrows T6 in FIG. 6, the heat generated from the semiconductor element 10 is transferred in the Y-axis direction in a range of the width of the semiconductor element 10 in the vertical heat dissipation portion 45. In addition, as indicated by arrows T7 in FIG. 6, the heat generated from the semiconductor element 10 is transferred in the X-axis direction in a range of the width of the semiconductor element 10 in the right lateral heat dissipation portion 46 and the left lateral heat dissipation portion 47. Therefore, as indicated by hatching LT in FIG. 6, a region to which heat is hardly transferred is formed outside the region to which heat is transferred in the X-axis direction and the Y-axis direction in the range of the width of the semiconductor element 10. Therefore, also in the semiconductor module 102 of the second comparative example, the entire region of the heat dissipation plate 20 cannot be effectively utilized.

In contrast to the first comparative example and the second comparative example described above, the semiconductor module 1 of the first embodiment has the following effects. In the first embodiment, the heat dissipation plate 20 included in the semiconductor module 1 includes the first heat dissipation portion 21 and the second heat dissipation portions 22 formed to include the material having anisotropic thermal conductivity. The first heat dissipation portion 21 is provided to include the position facing the semiconductor element 10 in the thickness direction of the heat dissipation plate 20, and has high thermal conductivity in the planar direction of the first virtual plane parallel to the thickness direction of the heat dissipation plate 20. The second heat dissipation portions 22 are connected to the first heat dissipation portion 21 in a direction parallel to the planar direction of the first virtual plane and perpendicular to the thickness direction of the heat dissipation plate 20, and has high thermal conductivity in the planar direction of the second virtual plane perpendicular to the thickness direction of the heat dissipation plate 20.

According to this configuration, the heat transferred from the semiconductor element 10 to the first heat dissipation portion 21 spreads in the planar direction of the first virtual plane at the position directly below the semiconductor element 10 in the first heat dissipation portion 21. Therefore, a part of the heat transferred from the semiconductor element 10 to the first heat dissipation portion 21 is dissipated from the cooling surface of the first heat dissipation portion 21, and the remaining part is transferred to the second heat dissipation portions 22. As indicated by the arrows T1 in FIG. 2, the heat transferred to the second heat dissipation portions 22 spreads in the second heat dissipation portion 22 in the planar direction of the second virtual plane perpendicular to the thickness direction of the heat dissipation plate 20. As indicated by the arrows T3 in FIG. 2, the heat is transferred from the second heat dissipation portions 22 to the portions of the first heat dissipation portion 21 extending in the Y-axis direction with respect to the position directly below the semiconductor element 10. The heat transferred from the second heat dissipation portions 22 to the first heat dissipation portion 21 spreads in the planar direction of the first virtual plane in the first heat dissipation portion 21, and is dissipated from the cooling surface of the first heat dissipation portion 21. As described above, in the first embodiment, since the second heat dissipation portions 22 functioning as the heat direction changing portions are disposed outside the first heat dissipation portion 21, it is possible to spread the heat generated by the semiconductor element 10 over a wide range of the heat dissipation plate 20 and dissipate the heat from the cooling surface of the heat dissipation plate 20. Therefore, in the semiconductor module 1, the area where the heat dissipation plate 20 functions as the heat dissipation surface can be increased, and the heat dissipation performance of the heat dissipation plate 20 can be improved.

In the first embodiment, the second heat dissipation portions 22 are connected to the portions of the first heat dissipation portion 21 extending in the direction parallel to the planar direction of the first virtual plane and perpendicular to the thickness direction of the heat dissipation plate 20 from the position directly below the semiconductor element 10. At the same time, the second heat dissipation portions 22 are also connected to the portions of the first heat dissipation portion 21 extending in the direction perpendicular to the planar direction of the first virtual plane from the position directly below the semiconductor element 10. Accordingly, as indicated by the arrows T1 in FIG. 2, the heat transferred from the semiconductor element 10 to the first heat dissipation portion 21 can be transferred to the second heat dissipation portions 22 and spread in the second heat dissipation portions 22. Then, as indicated by the arrows T3 in FIG. 2, the heat spreading in the second heat dissipation portions 22 can be transferred from the second heat dissipation portions 22 to the portions of the first heat dissipation portion 21 extending in the Y-axis direction from the position directly below the semiconductor element 10.

In the first embodiment, the heat dissipation plate 20 further includes the third heat dissipation portions 23. The third heat dissipation portions 23 are connected to the second heat dissipation portions 22 in the direction parallel to the planar direction of the second virtual plane. The third heat dissipation portion 23 has high thermal conductivity in the planar direction of the third virtual plane that is not perpendicular to the direction in which the third heat dissipation portions 23 are connected to the second heat dissipation portions 22 and is parallel to the thickness direction of the heat dissipation plate 20. With this configuration, as indicated by the arrows T2 in FIG. 2, the heat spreading from the semiconductor element 10 into the second heat dissipation portions 22 via the first heat dissipation portion 21 is transferred to the third heat dissipation portions 23. The heat spreads in the third heat dissipation portions 23 in the planar direction of the third virtual plane parallel to the thickness direction of the heat dissipation plate 20, and is dissipated from the cooling surfaces of the third heat dissipation portions 23. As described above, in the first embodiment, since the third heat dissipation portions 23 are disposed opposite to the first heat dissipation portion 21 across the second heat dissipation portions 22, it is possible to increase the amount of heat transferred from the heat dissipation plate 20 to the cooler 30. Therefore, in the semiconductor module 1, the area where the heat dissipation plate 20 functions as the heat dissipation surface can be increased, and the heat dissipation performance of the heat dissipation plate 20 can be improved.

In the first embodiment, the third virtual plane that defines the direction in which the third heat dissipation portions 23 have high thermal conductivity is parallel to the direction in which the third heat dissipation portions 23 are connected to the second heat dissipation portions 22 and parallel to the thickness direction. According to this configuration, in a case where the heat dissipation plate 20 is, for example, rectangular, it is possible to restrict formation of portions in the third heat dissipation portions 23 to which heat is not easily transferred, and to transfer the heat transferred from the semiconductor element 10 to the first heat dissipation portion 21 to the entire third heat dissipation portions 23 via the second heat dissipation portions 22. Therefore, the heat dissipation performance of the heat dissipation plate 20 can be improved.

In the first embodiment, the first virtual plane defining the direction in which the first heat dissipation portion 21 has high thermal conductivity and the third virtual plane defining the direction in which the third heat dissipation portions 23 have high thermal conductivity are parallel to the direction in which the first heat dissipation portion 21, the second heat dissipation portions 22, and the third heat dissipation portions 23 are arranged. According to this configuration, the orientations of the virtual planes defining the directions in which the first heat dissipation portion 21 and the third heat dissipation portions 23 have high thermal conductivity, specifically, the orientations of the multiple layers of the graphene 3 constituting the graphite 2 are set to the same as each other. Thus, the configuration of the heat dissipation plate 20 can be simplified, and the manufacturing process can be simplified. In addition, when the heat dissipation plate 20 is, for example, rectangular, it is possible to restrict the formation of the portions in the third heat dissipation portion 23 to which heat is not easily transferred, and to transfer the heat transferred from the semiconductor element 10 to the first heat dissipation portion 21 to the entire third heat dissipation portions 23 via the second heat dissipation portions 22. Therefore, the heat dissipation performance of the heat dissipation plate 20 can be improved.

### Second Embodiment

The following describes a second embodiment of the present disclosure. The second embodiment is similar to the first embodiment except for a part of the configuration of the heat dissipation plate 20 modified from the corresponding configuration of the first embodiment. Therefore, only parts different from the corresponding parts of the first embodiment will be described. In the drawings referred to in the description of the second and subsequent embodiments, the cooler 30 and the like are not illustrated.

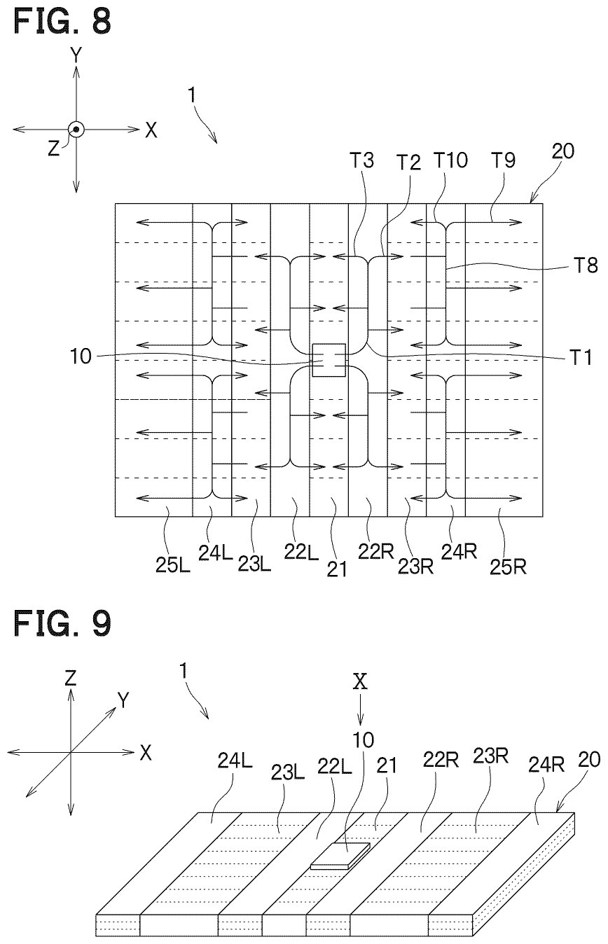

As shown in FIG. 7 and FIG. 8, in the second embodiment, the heat dissipation plate 20 has a first heat dissipation portion 21 to fifth heat dissipation portions 25. In the description of the second embodiment and the drawings referred to in the description, alphabetic symbols R and L indicating the positions of the respective heat dissipation portions are added to ends of the numerical symbols 22 to 25 that indicate the second heat dissipation portions 22 to the fifth heat dissipation portions 25. This also applies to the description of a third embodiment described later and the drawings referred to in the description.

The first heat dissipation portion 21, the second heat dissipation portions 22, and the third heat dissipation portions 23 are the same as those described in the first embodiment. The fourth heat dissipation portions 24 are portions connected to the third heat dissipation portions 23 in a direction parallel to the planar direction of the third virtual plane and perpendicular to the thickness direction of the heat dissipation plate 20. Specifically, the fourth heat dissipation portions 24 are portions connected to the third heat dissipation portions 23 in the X-axis direction. In the second embodiment, the heat dissipation plate 20 has two fourth heat dissipation portions 24. Of the two fourth heat dissipation portions 24, one disposed to the one side in the X-axis direction, that is, the right of the right third heat dissipation portion 23R is referred to as a right fourth heat dissipation portion 24R, and one disposed to the other side in the X-axis direction, that is, the left of the left third heat dissipation portion 23L is referred to as a left fourth heat dissipation portion 24L.

Similarly to the second heat dissipation portions 22, the fourth heat dissipation portions 24 have high thermal conductivity in a planar direction of a fourth virtual plane perpendicular to the thickness direction of the heat dissipation plate 20, that is, the XY plane. Therefore, the fourth heat dissipation portions 24 function as heat direction changing portions similarly to the second heat dissipation portions 22.

The fifth heat dissipation portions 25 are portions connected to the fourth heat dissipation portions 24 in any direction parallel to the planar direction of the fourth virtual plane, that is, the XY plane. In the second embodiment, all of the first heat dissipation portion 21 to the fifth heat dissipation portions 25 are arranged in the X-axis direction. The fifth heat dissipation portions 25 are portions connected to the fourth heat dissipation portions 24 in the X-axis direction. In the second embodiment, the heat dissipation plate 20 has two fifth heat dissipation portions 25. Of the two fifth heat dissipation portions 25, one disposed to the one side in the X-axis direction, that is, the right of the right fourth heat dissipation portion 24R is referred to as a right fifth heat dissipation portion 25R, and one disposed to the other side in the X-axis direction, that is, the left of the left fourth heat dissipation portion 24L is referred to as a left fifth heat dissipation portion 25L.

A plane that is not perpendicular to the direction in which the fifth heat dissipation portions 25 are connected to the fourth heat dissipation portions 24 and is parallel to the thickness direction of the heat dissipation plate 20 is referred to as a fifth virtual plane. The fifth heat dissipation portions 25 have high thermal conductivity in the planar direction of the fifth virtual plane. In the second embodiment, the fifth virtual plane is a plane parallel to the direction in which the fifth heat dissipation portions 25 are connected to the fourth heat dissipation portions 24 and parallel to the thickness direction of the heat dissipation plate 20. Therefore, the fifth virtual plane is the XZ plane, similarly to the first virtual plane and the third virtual plane. Therefore, the fifth heat dissipation portions 25 have high thermal conductivity in the planar direction of the XZ plane.

In FIG. 8, a part of paths through which heat generated from the semiconductor element 10 is transferred to the heat dissipation plate 20 is schematically indicated by arrows.

The heat transfer paths indicated by arrows T1 to T3 in FIG. 8 are the same as those described in the first embodiment.

As indicated by arrows T8, the heat transferred from the third heat dissipation portions 23 to the fourth heat dissipation portions 24 spreads along the XY plane in the fourth heat dissipation portions 24. As indicated by arrows T9, a part of the heat spread along the XY plane in the fourth heat dissipation portions 24 is transferred to the fifth heat dissipation portions 25 in the X-axis direction, then spreads in the fifth heat dissipation portions 25 along the XZ plane, and is dissipated from the cooling surfaces of the fifth heat dissipation portions 25. In addition, as indicated by arrows T10, another part of the heat spread along the XY plane in the fourth heat dissipation portions 24 is transferred to the third heat dissipation portions 23 in the X-axis direction, and is dissipated from the cooling surfaces of the third heat dissipation portions 23.

As described above, in the second embodiment, the second heat dissipation portions 22 and the fourth heat dissipation portions 24 are used as heat direction changing portions. Thus, the heat generated by the semiconductor element 10 can be spread to substantially the entire region of the heat dissipation plate 20 and dissipated from the cooling surface of the heat dissipation plate 20. Therefore, in the semiconductor module 1, the area where the heat dissipation plate 20 functions as the heat dissipation surface can be increased, and the heat dissipation performance of the heat dissipation plate 20 can be improved.

### Third Embodiment

The following describes a third embodiment of the present disclosure. The third embodiment is similar to the first embodiment except for a part of the configuration of the heat dissipation plate 20 modified from the corresponding configuration of the first embodiment. Therefore, only parts different from the corresponding parts of the first embodiment will be described.

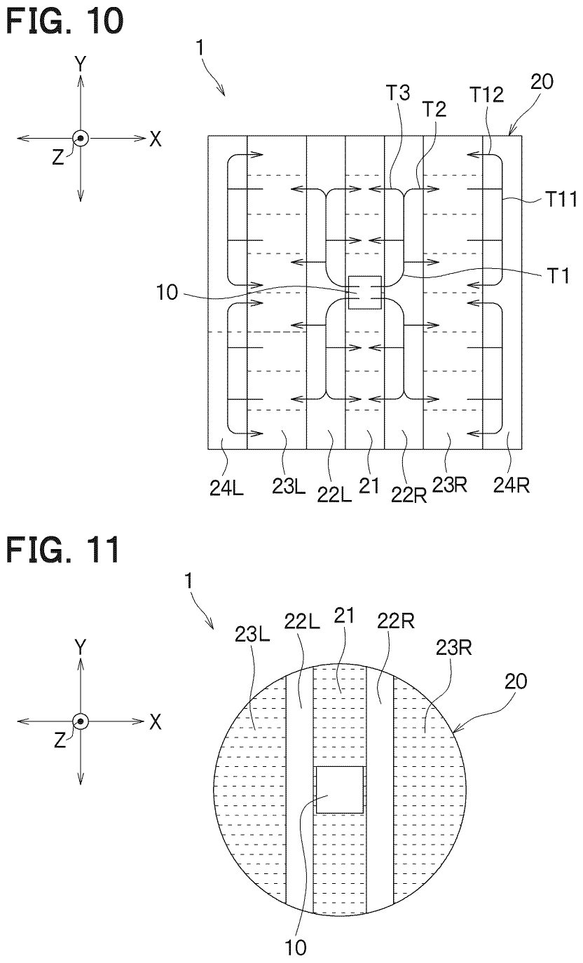

As shown in FIG. 9 and FIG. 10, in the third embodiment, the heat dissipation plate 20 has a first heat dissipation portion 21 to fourth heat dissipation portions 24. The first to fourth heat dissipation portions 21 to 24 are the same as those described in the second embodiment.

In FIG. 10, a part of paths through which heat generated from the semiconductor element 10 is transferred to the heat dissipation plate 20 is schematically indicated by arrows.

The heat transfer paths indicated by arrows T1 to T3 in FIG. 10 are the same as those described in the first embodiment. As indicated by arrows T11, the heat transferred from the third heat dissipation portions 23 to the fourth heat dissipation portions 24 spreads along the XY plane in the fourth heat dissipation portions 24. As indicated by arrows T12, the heat spread along the XY plane in the fourth heat dissipation portions 24 is transferred to the third heat dissipation portions 23 in the X-axis direction. Then, the heat spreads in the third heat dissipation portions 23 along the XZ plane, and is dissipated from the cooling surfaces of the third heat dissipation portions 23.

As described above, also in the third embodiment, the second heat dissipation portions 22 and the fourth heat dissipation portions 24 are used as heat direction changing portions. Thus, it is possible to spread the heat generated by the semiconductor element 10 to substantially the entire region of the heat dissipation plate 20 and dissipate the heat from the cooling surface of the heat dissipation plate 20. Therefore, in the semiconductor module 1, the area where the heat dissipation plate 20 functions as the heat dissipation surface can be increased, and the heat dissipation performance of the heat dissipation plate 20 can be improved.

### Fourth to Eighths embodiments

The following describes fourth to eighths embodiments of the present disclosure. Since the fourth to eighths embodiments are similar to the first embodiment except that the shape of the heat dissipation plate 20 is changed with respect to the first embodiment. Therefore, only parts different from corresponding parts of the first embodiment will be described.

### Fourth Embodiment

As shown in FIG. 11, in the fourth embodiment, the heat dissipation plate 20 has a circular shape in a plan view when viewed from the thickness direction of the heat dissipation plate 20. Outer edges of the first heat dissipation portion 21, the second heat dissipation portions 22, and the third heat dissipation portions 23 are all arc-shaped. The area of the right second heat dissipation portion 22R disposed to the right of the first heat dissipation portion 21 in FIG. 11 is the same as the area of the left second heat dissipation portion 22L disposed to the left of the first heat dissipation portion 21 in FIG. 11. The area of the right third heat dissipation portion 23R disposed to the right of the first heat dissipation portion 21 in FIG. 11 is equal to the area of the left third heat dissipation portion 23L disposed to the left of the first heat dissipation portion 21 in FIG. 11.

### Fifth Embodiment

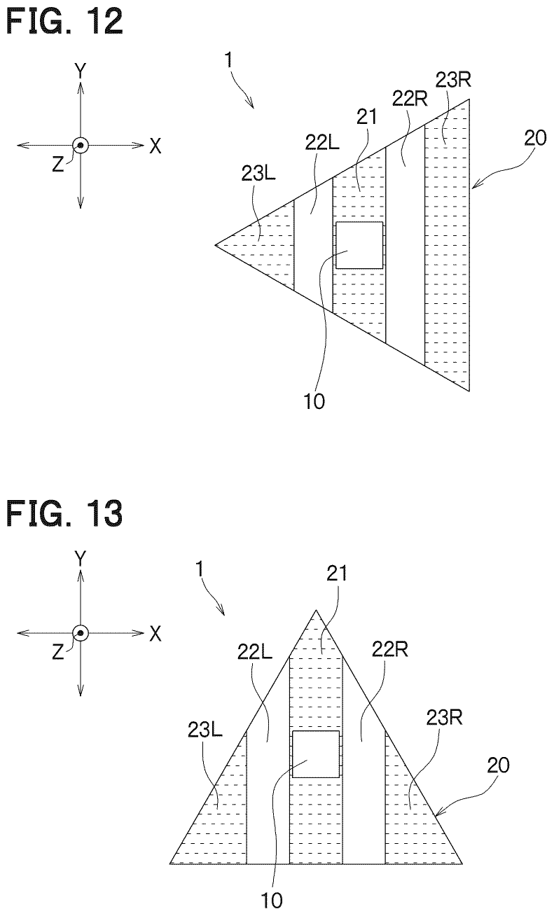

As shown in FIG. 12, in the fifth embodiment, the heat dissipation plate 20 has a triangular shape in a plan view viewed from the thickness direction of the heat dissipation plate 20. Two of the three vertices of the triangle are formed in the right third heat dissipation portion 23R disposed to the right of the first heat dissipation portion 21 in FIG. 12, and another vertex is formed in the left third heat dissipation portion 23L disposed to the left of the first heat dissipation portion 21 in FIG. 12.

The area of the right second heat dissipation portion 22R disposed to the right of the first heat dissipation portion 21 in FIG. 12 is larger than the area of the left second heat dissipation portion 22L disposed to the left of the first heat dissipation portion 21 in FIG. 12. The area of the right third heat dissipation portion 23R disposed to the right of the first heat dissipation portion 21 in FIG. 12 is larger than the area of the left third heat dissipation portion 23L disposed to the left of the first heat dissipation portion 21 in FIG. 12.

### Sixth Embodiment

As shown in FIG. 13, also in the sixth embodiment, the heat dissipation plate 20 has a triangular shape in a plan view viewed from the thickness direction of the heat dissipation plate 20. Of the three vertices of the triangle, one vertex is formed in a portion of the first heat dissipation portion 21 located on the upper side of FIG. 13, another vertex is formed in the right third heat dissipation portion 23R disposed to the right of the first heat dissipation portion 21 in FIG. 13, and the other vertex is formed in the left third heat dissipation portion 23L disposed to the left of the first heat dissipation portion 21 in FIG. 13.

The area of the right second heat dissipation portion 22R disposed to the right of the first heat dissipation portion 21 in FIG. 13 is the same as the area of the left second heat dissipation portion 22L disposed to the left of the first heat dissipation portion 21 in FIG. 13. The area of the right third heat dissipation portion 23R disposed to the right of the first heat dissipation portion 21 in FIG. 13 is the same as the area of the left third heat dissipation portion 23L disposed to the left of the first heat dissipation portion 21 in FIG. 13.

### Seventh Embodiment

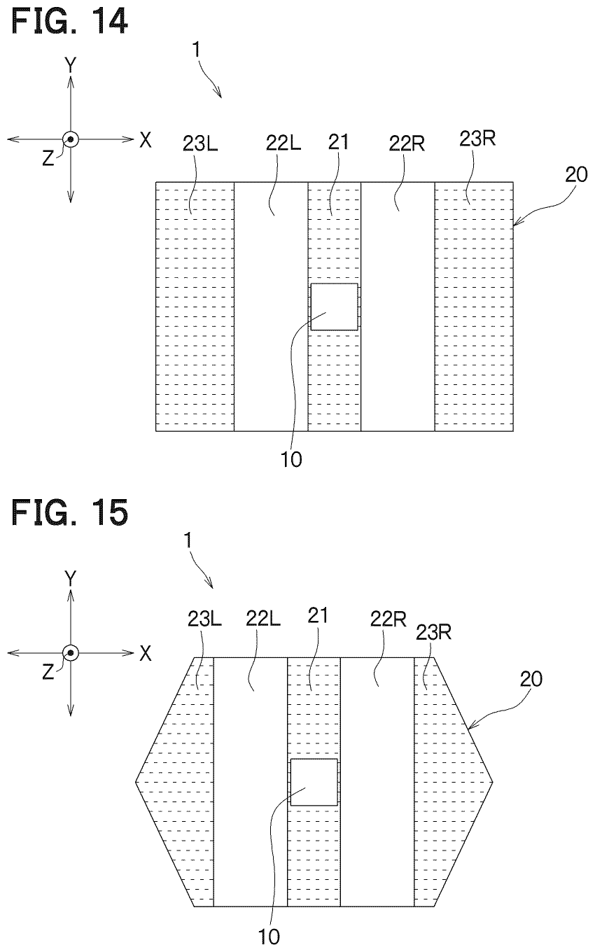

As shown in FIG. 14, in the seventh embodiment, the heat dissipation plate 20 has a rectangular shape in a plan view viewed from the thickness direction of the heat dissipation plate 20. Specifically, the heat dissipation plate 20 has a rectangular shape in which the length of the side in the X-axis direction is longer than the length of the side in the Y-axis direction. Although not illustrated, the heat dissipation plate 20 may have a rectangular shape in which the length of the side in the X-axis direction is shorter than the length of the side in the Y-axis direction.

### Eighth Embodiment

As shown in FIG. 15, in the eighth embodiment, the heat dissipation plate 20 has a hexagonal shape in a plan view when viewed from the thickness direction of the heat dissipation plate 20. Specifically, in the right third heat dissipation portion 23R disposed to the right of the first heat dissipation portion 21 in FIG. 15, a central portion in the Y-axis direction protrudes to the right in the X-axis direction. In addition, in the left third heat dissipation portion 23L disposed to the left of the first heat dissipation portion 21 in FIG. 15, a central portion in the Y-axis direction protrudes to the left in the X-axis direction. Of the six vertices of the hexagon, three vertices are formed in the right third heat dissipation portion 23R disposed to the right of the first heat dissipation portion 21 in FIG. 15, and the other three vertices are formed in the left third heat dissipation portion 23L disposed to the left of the first heat dissipation portion 21 in FIG. 15.

The shape of the heat dissipation plate 20 is not limited to the shapes exemplified in the first to eighth embodiments, and various shapes such as an elliptical shape or a polygonal shape can be adopted.

### Ninth to Twelfth Embodiments

The following describes ninth to twelfth embodiments of the present disclosure. The ninth to twelfth embodiments are similar to the first embodiment except that the shape or the mounting position of the semiconductor element 10 is changed from that of the first embodiment. Therefore, only parts different from the corresponding parts of the first embodiment will be described.

### Ninth Embodiment

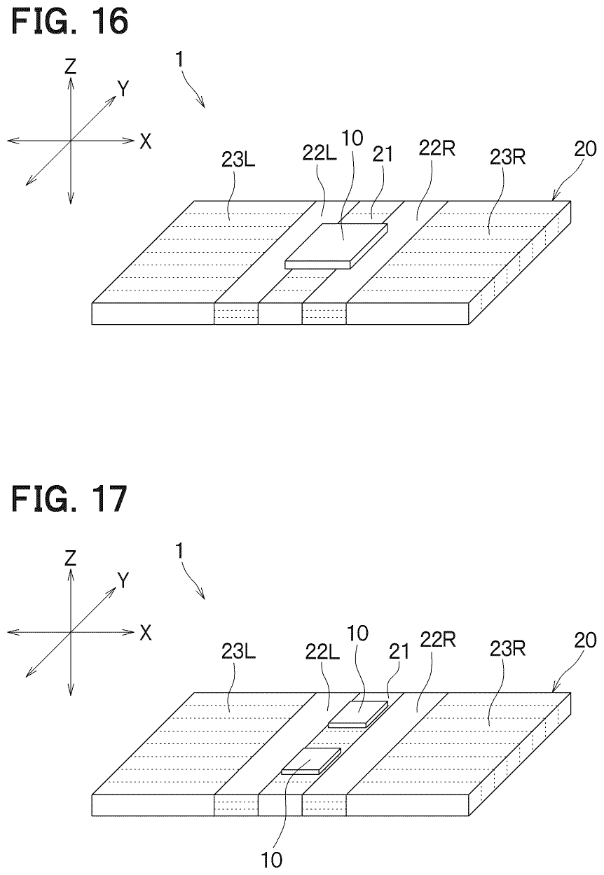

As shown in FIG. 16, in the ninth embodiment, at least a part of the semiconductor element 10 is provided so as to overlap both the first heat dissipation portion 21 and the second heat dissipation portions 22 in the thickness direction of the heat dissipation plate 20. That is, the semiconductor element 10 may be provided so that the semiconductor element 10 overlaps the second heat dissipation portions 22 in addition to the first heat dissipation portion 21.

### Tenth Embodiment

As shown in FIG. 17, in the tenth embodiment, multiple semiconductor elements 10 are disposed on the heat dissipation plate 20. Specifically, the two semiconductor elements 10 are both disposed on the first heat dissipation portion 21. As described above, multiple semiconductor elements 10 may be mounted on the heat dissipation plate 20. The number of the semiconductor elements 10 is not limited to two and can be set optionally, and the mounting positions of the semiconductor elements 10 can also be set optionally.

### Eleventh Embodiment

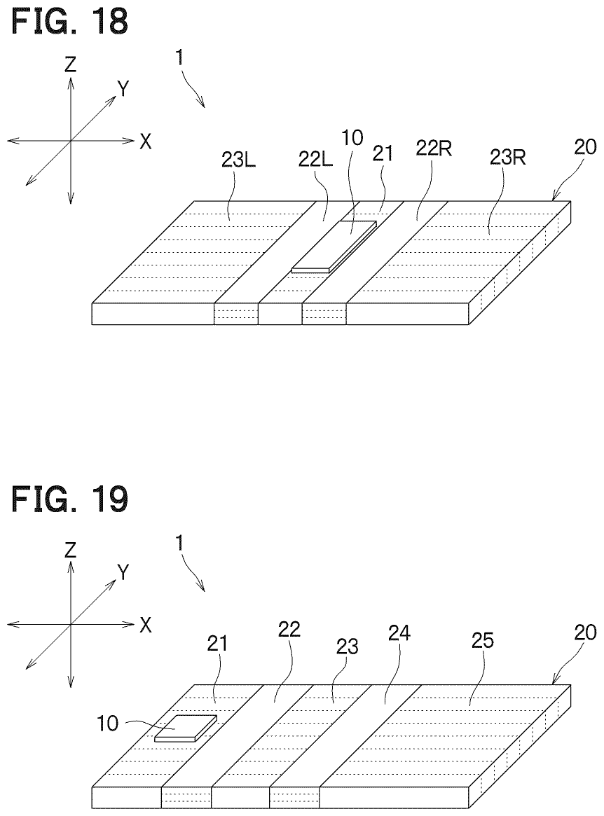

As shown in FIG. 18, in the eleventh embodiment, the semiconductor element 10 has a rectangular shape. In this way, the semiconductor element 10 may have any shape. The aspect ratio of the shape of the semiconductor element 10 can also be set optionally.

### Twelfth Embodiment

As shown in FIG. 19, in the twelfth embodiment, the semiconductor element 10 is disposed on a portion of the heat dissipation plate 20 close to the left side of the heat dissipation plate 20 in FIG. 19. It is sufficient that the semiconductor element 10 is disposed on one of the heat dissipation portions constituting the heat dissipation plate 20 that has high thermal conductivity in a planar direction of any virtual plane parallel to the thickness direction of the heat dissipation plate 20.

In the present disclosure, as described in the first embodiment, among the multiple heat dissipation portions constituting the heat dissipation plate 20, a heat dissipation portion that includes a position facing the semiconductor element 10 in the thickness direction of the heat dissipation plate 20 and has high thermal conductivity in a planar direction of a first virtual plane parallel to the thickness direction of the heat dissipation plate 20 is referred to as a first heat dissipation portion 21. Therefore, in the twelfth embodiment, the heat dissipation portion of the heat dissipation plate 20 disposed to the left in FIG. 19 is referred to as the first heat dissipation portion 21, and the heat dissipation portions disposed from the first heat dissipation portion 21 toward the right in FIG. 19 are referred to as a second heat dissipation portion 22 to a fifth heat dissipation portion 25. The second heat dissipation portion 22 and the fourth heat dissipation portion 24 function as heat direction changing portions.

### Thirteenth and Fourteenth Embodiments

The following describes thirteenth and fourteenth embodiments. The thirteenth and fourteenth embodiments are different from the first embodiment in that multiple heat dissipation portions constituting the heat dissipation plate 20 are radially arranged around the semiconductor element 10. Since the other parts are the same as those of the first embodiment, only parts different from the first embodiment will be described.

### Thirteenth Embodiment

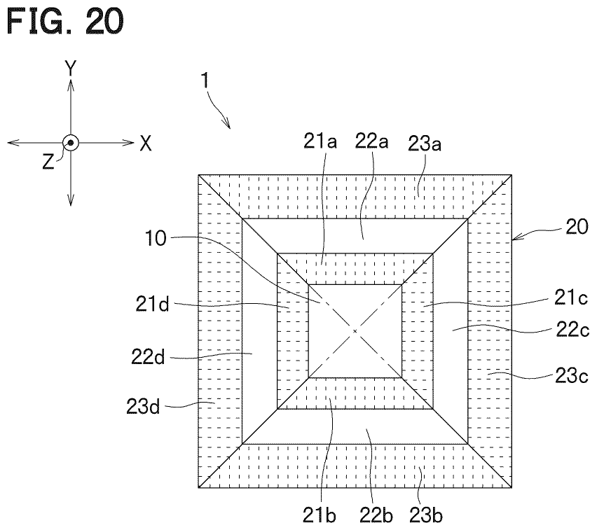

As shown in FIG. 20, in the heat dissipation plate 20 included in the semiconductor module 1 according to the thirteenth embodiment, the first heat dissipation portion 21, the second heat dissipation portion 22, and the third heat dissipation portion 23 are radially disposed around the semiconductor element 10. In other words, the second heat dissipation portion 22 is annularly disposed outside the first heat dissipation portion 21, and the third heat dissipation portion 23 is annularly disposed outside the second heat dissipation portion 22. The heat dissipation plate 20 has a quadrangular shape. Each of the first heat dissipation portion 21, the second heat dissipation portion 22, and the third heat dissipation portion 23 are divided into four sections by diagonal lines of the quadrangle.

In the description of the thirteenth embodiment and FIG. 20 referred to in the description, alphabetical symbols “a” to “d” indicating sections of the respective heat dissipation portions are added to the ends of the numerical symbols 22 to 23 indicating the first heat dissipation portion 21 to the third heat dissipation portion 23. In FIG. 20, the boundary lines of the first heat dissipation portion 21, the second heat dissipation portion 22, and the third heat dissipation portion 23 and boundary lines of the respective sections are all indicated by solid lines, but actually, they are integrally formed. In FIG. 20, portions of the boundary line between the sections of the first heat dissipation portion 21 below the semiconductor element 10 are indicated by alternate long and short dash lines. This also applies to the description of the fourteenth embodiment described later and the drawings referred to in the description.

Each section of the first heat dissipation portion 21 has high thermal conductivity in a planar direction of a first virtual plane that is any plane parallel to the thickness direction of the heat dissipation plate 20. Specifically, among the four sections of the first heat dissipation portion 21, a section 21a disposed to the upper side in FIG. 20 and a section 21b disposed to the lower side in FIG. 20 have high thermal conductivity in the planar direction of the YZ plane as the first virtual plane. Among the four sections of the first heat dissipation portion 21, a section 21c disposed to the right in FIG. 20 and a section 21d disposed to the left in FIG. 20 have high thermal conductivity in the planar direction of the XZ plane as the first virtual plane.

Each section of the second heat dissipation portion 22 is a portion connected to each section of the first heat dissipation portion 21 in a direction parallel to the planar direction of the first virtual plane and perpendicular to the thickness direction. Each section of the second heat dissipation portion 22 has high thermal conductivity in a planar direction of a second virtual plane perpendicular to the thickness direction of the heat dissipation plate 20. Specifically, each of the four sections 22a, 22b, 22c, and 22d of the second heat dissipation portion 22 has high thermal conductivity in the planar direction of the XY plane as the second virtual plane.

Each section of the third heat dissipation portion 23 is a portion connected to each section of the second heat dissipation portion 22 in any direction parallel to the planar direction of the second virtual plane. Each section of the third heat dissipation portion 23 has high thermal conductivity in a planar direction of a third virtual plane that is not perpendicular to a direction in which the third heat dissipation portion 23 is connected to the second heat dissipation portion 22 and is parallel to the thickness direction of the heat dissipation plate 20. Specifically, among the four sections of the third heat dissipation portion 23, a section 23a disposed to the upper side in FIG. 20 and a section 23b disposed to the lower side in FIG. 20 have high thermal conductivity in the planar direction of the YZ plane as the third virtual plane. Among the four sections of the third heat dissipation portion 23, a section 23c disposed to the right in FIG. 20 and a section 24d disposed to the left in FIG. 20 have high thermal conductivity in the planar direction of the XZ plane as the third virtual plane.

Also in the thirteenth embodiment described above, the heat generated by the semiconductor element 10 can be spread to substantially the entire region of the heat dissipation plate 20 by disposing the second heat dissipation portion 22 functioning as a heat direction changing portion between the first heat dissipation portion 21 and the third heat dissipation portion 23. Therefore, in the semiconductor module 1, the area where the heat dissipation plate 20 functions as a heat dissipation surface can be increased, and the heat dissipation performance of the heat dissipation plate 20 can be improved.

### Fourteenth Embodiment

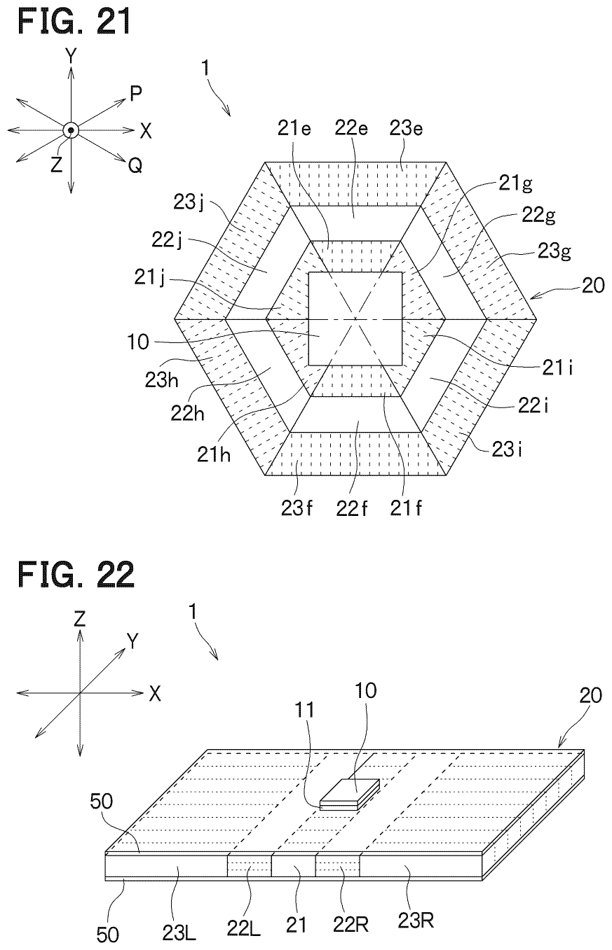

As shown in FIG. 21, also in the heat dissipation plate 20 included in the semiconductor module 1 according to the fourteenth embodiment, the first heat dissipation portion 21, the second heat dissipation portion 22, and the third heat dissipation portion 23 are radially disposed around the semiconductor element 10. In other words, the second heat dissipation portion 22 is annularly disposed outside the first heat dissipation portion 21, and the third heat dissipation portion 23 is annularly disposed outside the second heat dissipation portion 22. The heat dissipation plate 20 has a hexagonal shape. The first heat dissipation portion 21, the second heat dissipation portion 22, and the third heat dissipation portion 23 are divided into six sections by diagonal lines of the hexagon. In FIG. 21, alphabet symbols “e” to “j” indicating sections of the respective heat dissipation portions are added to the ends of the numeral symbols 22 to 23 indicating the first heat dissipation portion 21 to the third heat dissipation portion 23.

In FIG. 21, a P-axis and a Q-axis are added to the three-dimensional coordinates of the X-axis, the Y-axis, and the Z-axis. The P-axis is an axis rotated counterclockwise by 30 degrees with respect to the X-axis in the XY plane, and the Q-axis is an axis rotated clockwise by 30 degrees with respect to the X-axis in the XY plane.

Each section of the first heat dissipation portion 21 has high thermal conductivity in a planar direction of a first virtual plane that is a plane parallel to the thickness direction of the heat dissipation plate 20. Specifically, among the six sections of the first heat dissipation portion 21, a section 21e disposed to the upper side in FIG. 21 and the section 21f disposed to the lower side in FIG. 21 have high thermal conductivity in the planar direction of the YZ plane as the first virtual plane. Among the six sections of the first heat dissipation portion 21, a section 21g disposed to the upper right side in FIG. 21 and a section 21h disposed to the lower left side in FIG. 21 have high thermal conductivity in the planar direction of the PZ plane as the first virtual plane. Among the six sections of the first heat dissipation portion 21, a section 21i disposed to the lower right side in FIG. 21 and a section 21j disposed to the upper left side in FIG. 21 have high thermal conductivity in the planar direction of the QZ plane as the first virtual plane.

Each section of the second heat dissipation portion 22 is a portion connected to each section of the first heat dissipation portion 21 in a direction parallel to the planar direction of the first virtual plane and perpendicular to the thickness direction. Each section of the second heat dissipation portion 22 has high thermal conductivity in a planar direction of a second virtual plane perpendicular to the thickness direction of the heat dissipation plate 20. Specifically, each of the six sections 22e, 21f, 21g, 21h, 21i, and 21j of the second heat dissipation portion 22 has high thermal conductivity in the planar direction of the XY plane as the second virtual plane.

The third heat dissipation portion 23 is a portion connected to the second heat dissipation portion 22 in any direction parallel to the planar direction of the second virtual plane. The third heat dissipation portion 23 has high thermal conductivity in a planar direction of a third virtual plane that is not perpendicular to a direction in which the third heat dissipation portion 23 is connected to the second heat dissipation portion 22 and is parallel to the thickness direction of the heat dissipation plate 20. Specifically, among the six sections of the third heat dissipation portion 23, a section 23e disposed to the upper side in FIG. 21 and a section 23f disposed to lower side in FIG. 21 have high thermal conductivity in the planar direction of the YZ plane as the third virtual plane. Among the six sections of the third heat dissipation portion 23, a section 23g disposed to the upper right side in FIG. 21 and a section 23h disposed to the lower left side in FIG. 21 have high thermal conductivity in the planar direction of the PZ plane as the third virtual plane. Among the six sections of the third heat dissipation portion 23, a section 23i disposed to the lower right side in FIG. 21 and a section 23j disposed to the upper left side in FIG. 21 have high thermal conductivity in the planar direction of the QZ plane as the third virtual plane.

Also in the fourteenth embodiment described above, the heat generated by the semiconductor element 10 can be spread to substantially the entire region of the heat dissipation plate 20 by disposing the second heat dissipation portion 22 functioning as a heat direction changing portion between the first heat dissipation portion 21 and the third heat dissipation portion 23. Therefore, in the semiconductor module 1, the area where the heat dissipation plate 20 functions as the heat dissipation surface can be increased, and the heat dissipation performance of the heat dissipation plate 20 can be improved.

### Fifteenth Embodiment

The following describes a fifteenth embodiment of the present disclosure. The fifteenth embodiment is similar to the first embodiment except for a part of the configuration of the heat dissipation plate 20 modified from the corresponding configuration of the first embodiment. Therefore, only parts different from the corresponding parts of the first embodiment will be described.

As shown in FIG. 22, in the fifteenth embodiment, the heat dissipation plate 20 has metal plates 50 on one surface and the other surface facing in the thickness direction with respect to the first heat dissipation portion 21, the second heat dissipation portions 22, and the third heat dissipation portions 23. In other words, the heat dissipation plate 20 has the metal plate 50 on each of the element mounting surface and the cooling surface. The metal plate 50 is formed of a material having a low electrical resistivity, such as copper.

The semiconductor element 10 is bonded to the metal plate 50 disposed to the element mounting surface of the heat dissipation plate 20 by a bonding material 11. The bonding material 11 is, for example, solder.

In the semiconductor module 1 of the fifteenth embodiment described above, the metal plate 50 is disposed to the element mounting surface of the heat dissipation plate 20. Thus, the metal plate 50 can be used as wiring for energizing the semiconductor element 10, and the functionality of the semiconductor module 1 can be improved.

Furthermore, since the metal plate 50 is disposed to each of the element mounting surface and the cooling surface of the heat dissipation plate 20, in the first heat dissipation portion 21 and the third heat dissipation portions 23, heat can be further spread in the direction perpendicular to the thickness direction of the heat dissipation plate 20, that is, in the planar direction of the XY plane via the metal plate 50. Therefore, it is possible to spread the heat to substantially the entire region of the heat dissipation plate 20 and improve the heat dissipation performance of the heat dissipation plate 20.

The following describes results of analyzing a temperature distribution during heat generation of the semiconductor element 10 in the semiconductor module 1 described in the fifteenth embodiment and a semiconductor module 103 according to a third comparative example.

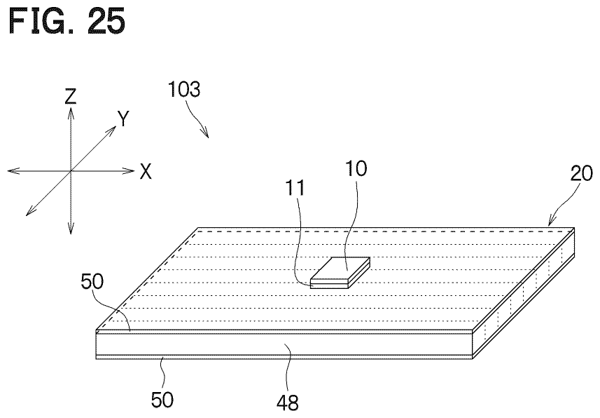

First, a configuration of the semiconductor module 103 of the third comparative example to be compared will be described. As shown in FIG. 25, the semiconductor module 103 of the third comparative example includes the semiconductor element 10, the heat dissipation plate 20, and the like. The semiconductor element 10 is the same as that of the fifteenth embodiment. The heat dissipation plate 20 has one heat dissipation portion 48 formed of the graphite 2, and metal plates 50 respectively disposed to an element mounting surface and a cooling surface of the heat dissipation portion 48. The one heat dissipation portion 48 of the heat dissipation plate 20 has high thermal conductivity in the planar direction of the XZ plane. The metal plates 50 are made of copper as in the fifteenth embodiment.

A steady-state thermal analysis was performed on the semiconductor module 1 described in the fifteenth embodiment and the semiconductor module 103 of the third comparative example. The steady-state thermal analysis is performed under the condition that the amount of heat generated by the semiconductor element 10 is constant and cooling water having a water temperature of 30° C. flows through the cooler 30 disposed to the cooling surface of the heat dissipation plate 20. The size of the heat dissipation plate 20 was 40 mm in the X-axis direction and 20 mm in the Y-axis direction. The size of the semiconductor element 10 was 6.5 mm in both the X-axis direction and the Y-axis direction. In the semiconductor module 1 of the fifteenth embodiment, the size of the first heat dissipation portion 21 in the X-axis direction is 6.5 mm, and the size of each of the second heat dissipation portions 22R and 22L in the X-axis direction is 5 mm.

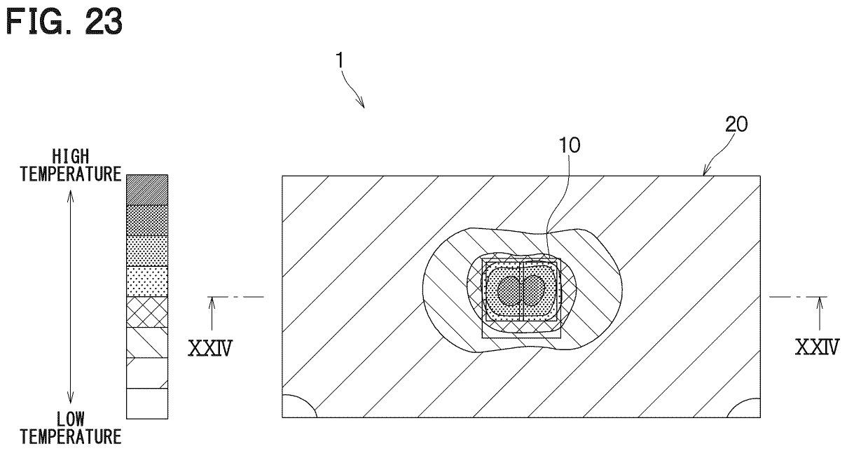

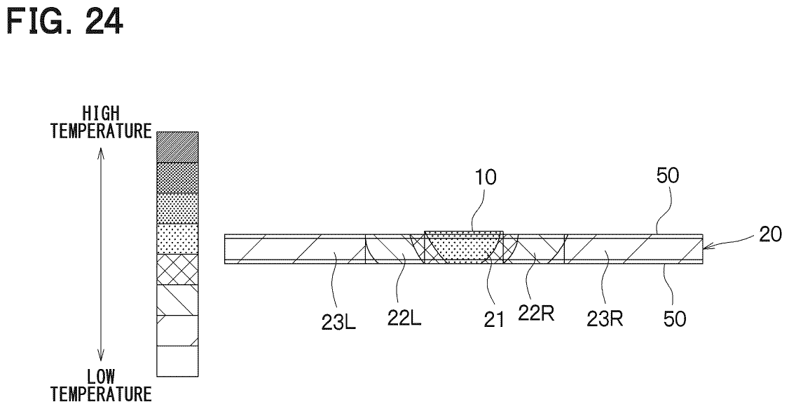

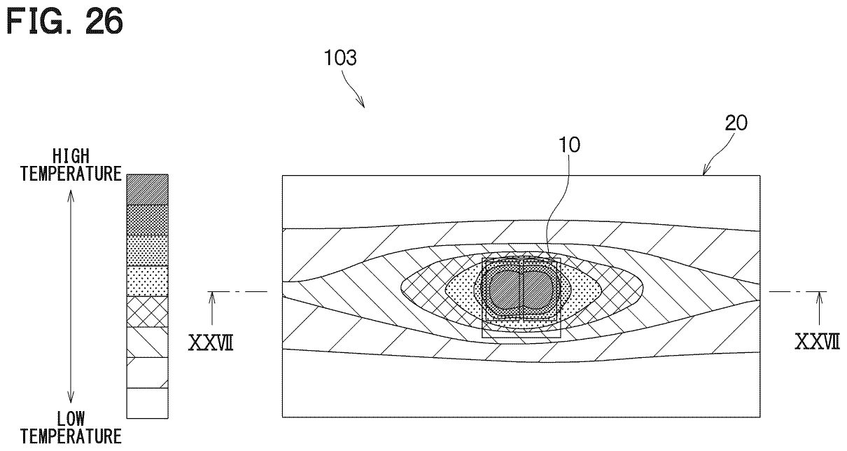

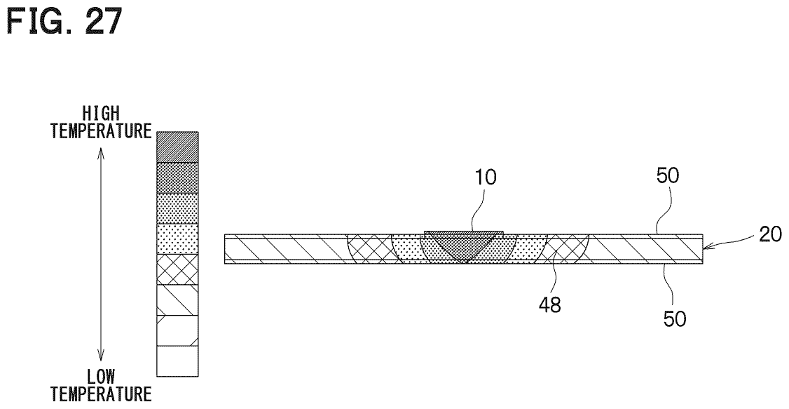

The analysis results of the semiconductor module 1 of the fifteenth embodiment are shown in FIG. 23 and FIG. 24, and the analysis results of the semiconductor module 103 of the third comparative example are shown in FIG. 26 and FIG. 27.

As a result of the analysis, the temperature of the heat dissipation plate 20 included in the semiconductor module 1 of the fifteenth embodiment is more uniform over the entire region of the heat dissipation plate 20 as compared with the temperature of the heat dissipation plate 20 included in the semiconductor module 103 of the third comparative example. According to this result, it can be said that the heat dissipation plate 20 included in the semiconductor module 1 of the fifteenth embodiment can dissipate heat using the entire region of the heat dissipation plate 20 as compared with the heat dissipation plate 20 included in the semiconductor module 103 of the third comparative example.

In contrast, in the heat dissipation plate 20 included in the semiconductor module 103 of the third comparative example, the temperature of a portion on one side and a portion on the other side in the Y-axis direction are lower than those of the heat dissipation plate 20 included in the semiconductor module 1 of the fifteenth embodiment. Thus, the heat dissipation plate 20 included in the semiconductor module 103 of the third comparative example has portions where heat is less likely to be transferred to the heat dissipation plate 20, that is, useless portions, as compared with the heat dissipation plate 20 included in the semiconductor module 1 of the fifteenth embodiment.

Regarding the temperature of the semiconductor element 10, the maximum temperature of the semiconductor element 10 included in the semiconductor module 103 of the third comparative example was 150° C. whereas the maximum temperature of the semiconductor element 10 included in the semiconductor module 1 of the fifteenth embodiment was 127° C. Therefore, it was found that the semiconductor module 1 of the fifteenth embodiment can lower the temperature of the semiconductor element 10 by dissipating heat using the entire region of the heat dissipation plate 20 as compared with the semiconductor module 103 of the third comparative example.

### Sixteenth Embodiment

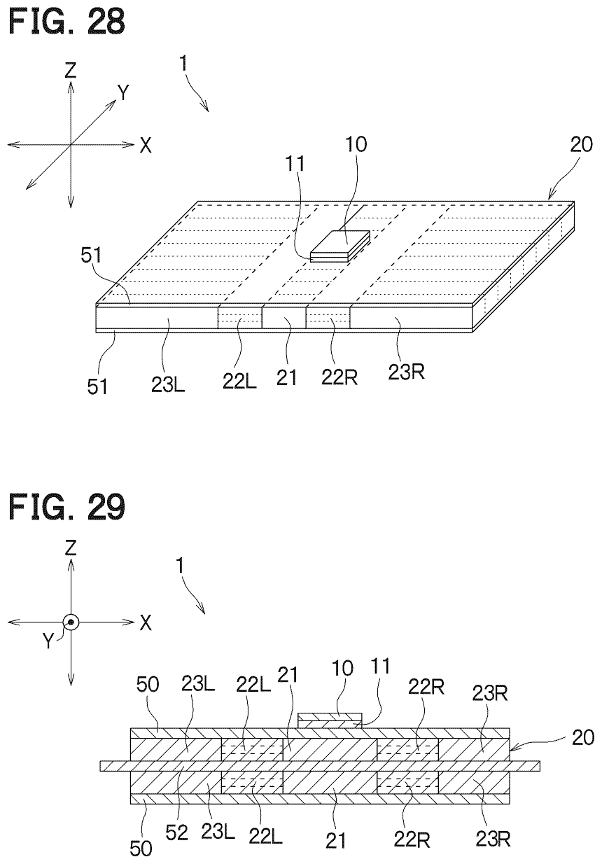

The following describes a sixteenth embodiment of the present disclosure. The sixteenth embodiment is a modification of the fifteenth embodiment. In the fifteenth embodiment, the metal plate 50 is disposed to each of the element mounting surface and the cooling surface of the heat dissipation plate 20. On the other hand, in the sixteenth embodiment, as shown in FIG. 28, an insulator 51 is disposed to each of the element mounting surface and the cooling surface of the heat dissipation plate 20. The insulator 51 is, for example, ceramic. The ceramic preferably has high thermal conductivity.

According to this configuration, it is possible to electrically insulate the semiconductor module 1 from the outside. In addition, in the first heat dissipation portion 21 and the third heat dissipation portions 23, heat is further spread in the direction perpendicular to the thickness direction of the heat dissipation plate 20, that is, in the planar direction of the XY plane via the insulator 51, and thus the heat dissipation performance of the heat dissipation plate 20 can be improved.

As another modification of the fifteenth and sixteenth embodiments, although not shown, the metal plate 50 may be disposed to the element mounting surface of the heat dissipation plate 20, and the insulator 51 may be disposed to the cooling surface. According to this configuration, the metal plate 50 disposed to the element mounting surface of the heat dissipation plate 20 can be used as wiring, and the semiconductor module 1 can be electrically insulated from the outside by the insulator 51 disposed to the cooling surface of the heat dissipation plate 20.

The metal plate 50 or the insulator 51 may be disposed to the entire surface of the heat dissipation plate 20 facing in the thickness direction, or the metal plate 50 or the insulator 51 may be disposed to a part of the surface of the heat dissipation plate 20.

### Seventeenth Embodiment

The following describes a seventeenth embodiment of the present disclosure. In the seventeenth embodiment, a part of the configuration of the heat dissipation plate 20 is changed with respect to the fifteenth and sixteenth embodiments.

As shown in FIG. 29, in the seventeenth embodiment, the heat dissipation plate 20 includes an insulator 52 having a plate shape at an intermediate position in the thickness direction. The insulator 52 is, for example, ceramic. The ceramic preferably has high thermal conductivity. The heat dissipation plate 20 further includes metal plates 50 disposed to the element mounting surface and the cooling surface, respectively, as in the fifteenth embodiment. The metal plate 50 is formed of a material having a low electrical resistivity, such as copper.

The semiconductor module 1 of the seventeenth embodiment described above can electrically insulate the semiconductor module 1 from the outside since the insulator 52 is disposed at the intermediate position in the thickness direction of the heat dissipation plate 20. The metal plate 50 disposed to the element mounting surface of the heat dissipation plate 20 can be used as wiring. Furthermore, in the first heat dissipation portion 21 and the third heat dissipation portions 23, heat is further spread in the direction perpendicular to the thickness direction of the heat dissipation plate 20, that is, in the planar direction of the XY plane via the metal plates 50 and the insulator 52, and thus the heat dissipation performance of the heat dissipation plate 20 can be improved.

As a modification of the seventeenth embodiment, the metal plate 50 may be disposed instead of or together with the insulator 52 at the intermediate position in the thickness direction of the heat dissipation plate 20.

As another modification of the seventeenth embodiment, the insulator 51 may be disposed instead of the metal plate 50 to at least one of the element mounting surface and the cooling surface of the heat dissipation plate 20.

### Eighteenth Embodiment

The following describes an eighteenth embodiment of the present disclosure. In the eighteenth embodiment, a part of the configuration of the heat dissipation plate 20 is changed with respect to the first embodiment.

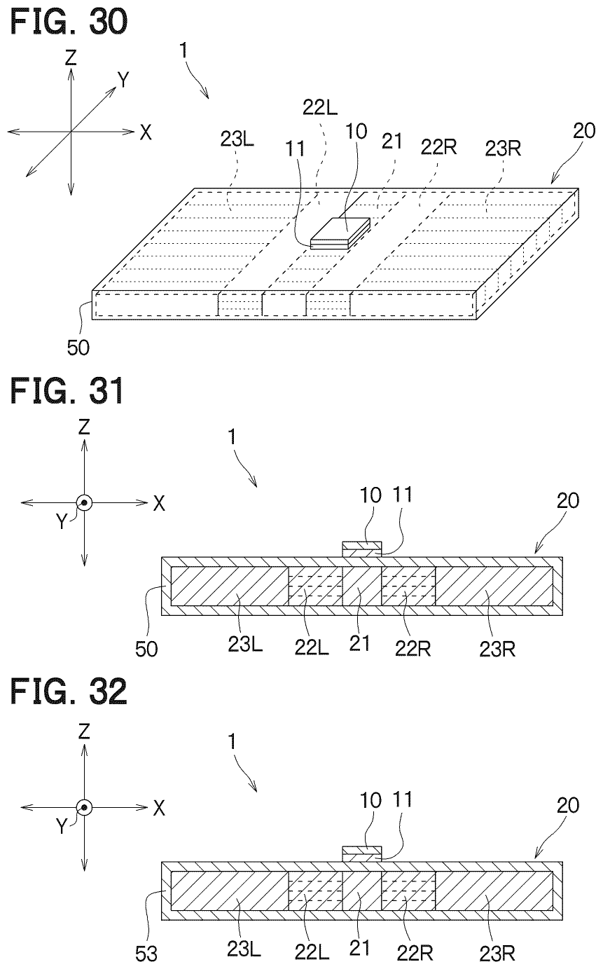

As shown in FIG. 30 and FIG. 31, in the eighteenth embodiment, the heat dissipation plate 20 includes a metal plate 50 that covers surfaces facing in the thickness direction and surfaces facing in a direction perpendicular to the thickness direction. In other words, the heat dissipation portions constituting the heat dissipation plate 20 are covered with the metal plate 50 in a capsule shape. The metal plate 50 is made of a material having a low electrical resistivity, such as copper.

The semiconductor element 10 is bonded to the metal plate 50 disposed to the element mounting surface of the heat dissipation plate 20 by a bonding material 11. The bonding material 11 is, for example, solder.

The semiconductor module 1 of the eighteenth embodiment described above can achieve effects similar to those of the semiconductor module 1 of the fifteenth embodiment. Furthermore, in the semiconductor module 1 of the eighteenth embodiment, the rigidity of the heat dissipation plate 20 can be increased by the metal plate 50 covering the heat dissipation portions in the capsule shape.

As a modification of the eighteenth embodiment, the metal plate 50 may partially cover the heat dissipation plate 20.

### Nineteenth Embodiment

The following describes a nineteenth embodiment of the present disclosure. In the nineteenth embodiment, a part of the configuration of the heat dissipation plate 20 is changed with respect to the first embodiment.

As shown in FIG. 32, in the nineteenth embodiment, the heat dissipation plate 20 includes a plating layer 53 that covers surfaces facing in the thickness direction and surfaces facing in a direction perpendicular to the thickness direction. In other words, the heat dissipation portions constituting the heat dissipation plate 20 are covered with the plating layer 53.

The semiconductor element 10 is bonded to the plating layer 53 disposed to the element mounting surface of the heat dissipation plate 20 by a bonding material 11. The bonding material 11 is, for example, solder.

The semiconductor module 1 of the nineteenth embodiment described above can achieve effects similar to those of the semiconductor module 1 of the eighteenth embodiment.

As a modification of the eighteenth embodiment, the plating layer 53 may partially cover the heat dissipation plate 20.

### Twentieth Embodiment

The following describes a twentieth embodiment of the present disclosure. The twentieth embodiment is similar to the first embodiment except for a part of the configuration of the heat dissipation plate 20 modified from the corresponding configuration of the first embodiment. Therefore, only parts different from the corresponding parts of the first embodiment will be described.

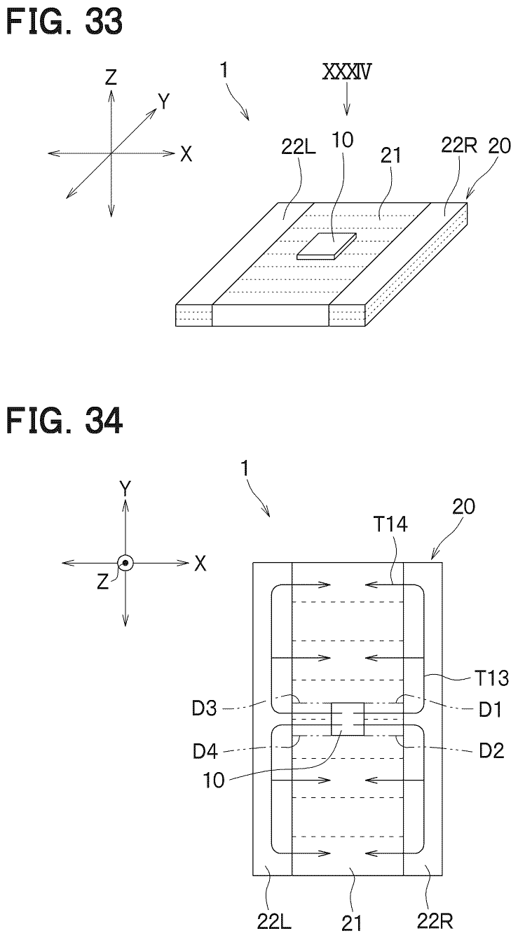

As shown in FIG. 33 and FIG. 34, in the twentieth embodiment, the heat dissipation plate 20 includes a first heat dissipation portion 21 and a second heat dissipation portion 22. The first heat dissipation portion 21 and the second heat dissipation portion 22 are the same as those described in the first embodiment. Note that, in FIG. 34, boundaries between a portion of the first heat dissipation portion 21 extending in the X-axis direction with respect to the position directly below the semiconductor element 10 and portions of the first heat dissipation portion 21 extending in a direction perpendicular to the planar direction of the first virtual plane with respect to the position directly below the semiconductor element 10 are indicated by two-dot chain lines D1 to D4 for description. The second heat dissipation portions 22 are connected to the portion of the first heat dissipation portion 21 extending in the X-axis direction with respect to the position directly below the semiconductor element 10, and are also connected in the X-axis direction to the portions of the first heat dissipation portion 21 extending in the direction perpendicular to the planar direction of the first virtual plane with respect to the position directly below the semiconductor element 10.

In FIG. 34, a part of paths through which heat generated from the semiconductor element 10 is transferred to the heat dissipation plate 20 is schematically indicated by arrows.

The heat generated from the semiconductor element 10 is transferred to the position of the first heat dissipation portion 21 directly below the semiconductor element 10, and then transferred to the second heat dissipation portions 22 in the X-axis direction from the position as indicated by arrows T13 in FIG. 34. Then, the heat spreads along the XY plane in the second heat dissipation portions 22. Although the arrows are omitted, a part of the heat transferred from the semiconductor element 10 to the position directly below the semiconductor element 10 in the first heat dissipation portion 21 spreads along the XZ plane at the position directly below the semiconductor element 10 in the first heat dissipation portion 21, and is dissipated from the cooling surface of the first heat dissipation portion 21.

As indicated by arrows T14, the heat spread along the XY plane in the second heat dissipation portion 22 is transferred to the portion of the first heat dissipation portion 21 extending in the Y-axis direction with respect to the position directly below the semiconductor element 10. Then, the heat spreads along the XZ plane at the portions of the first heat dissipation portion 21 extending in the Y-axis direction with respect to the position directly below the semiconductor element 10, and is dissipated from the cooling surface of the first heat dissipation portion 21.

As described above, also in the semiconductor module 1 according to the twentieth embodiment, the second heat dissipation portions 22 are used as heat direction changing portions. Thus, it is possible to spread the heat generated by the semiconductor element 10 to substantially the entire region of the heat dissipation plate 20 and dissipate the heat from the cooling surface of the heat dissipation plate 20. Therefore, in the semiconductor module 1, the area where the heat dissipation plate 20 functions as the heat dissipation surface can be increased, and the heat dissipation performance of the heat dissipation plate 20 can be improved.

In the twentieth embodiment, the second heat dissipation portions 22R and 22L are respectively disposed to one side and the other side in the X-axis direction with respect to the first heat dissipation portion 21. As a modification of the twentieth embodiment, the second heat dissipation portion 22 may be disposed only to one side or the other side in the X-axis direction with respect to the first heat dissipation portion 21.

### Other Embodiments

In each of the above-described embodiments, the heat dissipation plate 20 included in the semiconductor module 1 is arranged such that the multiple heat dissipation portions are linearly arranged, but the present disclosure is not limited thereto. For example, the multiple heat dissipation portions may be arranged so as to be bent, for example, in an L shape or a U shape.

In each of the above-described embodiments, the third virtual plane that defines the direction in which the third heat dissipation portion 23 has high thermal conductivity is parallel to the direction in which the third heat dissipation portion 23 is connected to the second heat dissipation portion 22 and parallel to the thickness direction, but the present disclosure is not limited thereto. For example, the third virtual plane may be at any angle except for being perpendicular to the direction in which the third heat dissipation portion 23 is connected to the second heat dissipation portion 22.

In each of the above-described embodiments, the first virtual plane defining the direction in which the first heat dissipation portion 21 has high thermal conductivity and the third virtual plane defining the direction in which the third heat dissipation portion 23 has high thermal conductivity are parallel to each other, but the present disclosure is not limited thereto. For example, the first virtual plane and the third virtual plane may form any angle.

The present disclosure is not limited to the embodiments described above, but can be modified appropriately within the scope recited in the claims. The above-described embodiments and a part thereof are not irrelevant to each other, and can be appropriately combined with each other unless the combination is obviously impossible. The constituent element(s) of each of the above embodiments is/are not necessarily essential unless it is specifically stated that the constituent element(s) is/are essential in the above embodiment, or unless the constituent element(s) is/are obviously essential in principle. A quantity, a value, an amount, a range, or the like, if specified in the above-described example embodiments, is not necessarily limited to the specific value, amount, range, or the like unless it is specifically stated that the value, amount, range, or the like is necessarily the specific value, amount, range, or the like, or unless the value, amount, range, or the like is obviously necessary to be the specific value, amount, range, or the like in principle. Further, in each of the above embodiments, when the shape of an element or the positional relationship between elements is mentioned, the present disclosure is not limited to the specific shape or positional relationship unless otherwise particularly specified or unless the present disclosure is limited to the specific shape or positional relationship in principle.

What is claimed is:

1. A semiconductor module comprising:
a heat dissipation plate having a plate shape; and
a semiconductor element mounted to the heat dissipation plate in a thickness direction of the heat dissipation plate and generating heat when supplied with electricity, wherein
the heat dissipation plate includes a first heat dissipation portion and a second heat dissipation portion formed of a material having anisotropic thermal conductivity,
the first heat dissipation portion includes a position facing the semiconductor element in the thickness direction, and has higher thermal conductivity in a planar direction of a first virtual plane parallel to the thickness direction than in a direction perpendicular to the planar direction of the first virtual plane, and
the second heat dissipation portion is connected to the first heat dissipation portion in a direction parallel to the planar direction of the first virtual plane and perpendicular to the thickness direction, and has higher thermal conductivity in a planar direction of a second virtual plane perpendicular to the thickness direction than in a direction perpendicular to the planar direction of the second virtual plane.

2. The semiconductor module according to claim 1, wherein
the second heat dissipation portion is connected to a portion of the first heat dissipation portion extending in a direction parallel to the planar direction of the first virtual plane and perpendicular to the thickness direction of the heat dissipation plate from the position facing the semiconductor element, and is also connected to a portion of the first heat dissipation portion extending in a direction perpendicular to the planar direction of the first virtual plane from the position facing the semiconductor element.

3. The semiconductor module according to claim 1, wherein
the heat dissipation plate further includes a third heat dissipation portion, and
the third heat dissipation portion is connected to the second heat dissipation portion in a direction parallel to the planar direction of the second virtual plane, and has higher thermal conductivity in a planar direction of a third virtual plane that is not perpendicular to a direction in which the third heat dissipation portion is connected to the second heat dissipation portion and is parallel to the thickness direction than in a direction perpendicular to the planar direction of the third virtual plane.

4. The semiconductor module according to claim 3, wherein
the third virtual plane is parallel to a direction in which the third heat dissipation portion is connected to the second heat dissipation portion and is parallel to the thickness direction.

5. The semiconductor module according to claim 3, wherein
the first virtual plane and the third virtual plane are parallel to a direction in which the first heat dissipation portion, the second heat dissipation portion, and the third heat dissipation portion are arranged.

6. The semiconductor module according to claim 1, wherein
the heat dissipation plate further includes a metal plate, and
the metal plate is disposed on a surface of the heat dissipation plate facing the thickness direction or at an intermediate position in the thickness direction of the heat dissipation plate.

7. The semiconductor module according to claim 1, wherein
the heat dissipation plate further includes an insulator having a plate shape, and
the insulator is disposed on a surface of the heat dissipation plate facing the thickness direction or at an intermediate position in the thickness direction of the heat dissipation plate.

8. The semiconductor module according to claim 1, wherein
the heat dissipation plate further includes a metal plate, and
the metal plate covers surfaces of the heat dissipation plate facing the thickness direction and surfaces of the heat dissipation plate facing a direction perpendicular to the thickness direction.

9. The semiconductor module according to claim 1, wherein
the heat dissipation plate further includes a metal plating layer disposed on a surface of the heat dissipation plate facing the thickness direction.

10. A heat dissipation plate comprising:
a first heat dissipation portion and a second heat dissipation portion formed of a material having anisotropic thermal conductivity, wherein
the first heat dissipation portion includes a position to face a semiconductor element that is to be mounted to the heat dissipation plate in a thickness direction of the heat dissipation plate, and has higher thermal conductivity in a planar direction of a first virtual plane parallel to the thickness direction than in a direction perpendicular to the planar direction of the first virtual plane, and
the second heat dissipation portion is connected to the first heat dissipation portion in a direction parallel to the planar direction of the first virtual plane and perpendicular to the thickness direction, and has higher thermal conductivity in a planar direction of a second virtual plane perpendicular to the thickness direction than in a direction perpendicular to the planar direction of the second virtual plane.
